(19) United States
(12) Patent Application Publication
(10) Pub. No.: US 2024/0395796 A1
(43) Pub. Date: Nov. 28, 2024

(54) SEMICONDUCTOR DEVICE

(71) Applicant: ROHM CO., LTD., Kyoto (JP)

(72) Inventors: Tadao YUKI, Kyoto-shi (JP); Michiko KIHARA, Kyoto-shi (JP)

(73) Assignee: ROHM CO., LTD., Kyoto (JP)

(21) Appl. No.: 18/794,649

(22) Filed: Aug. 5, 2024

Related U.S. Application Data
(63) Continuation of application No. PCT/JP2023/007193, filed on Feb. 28, 2023.

(30) Foreign Application Priority Data
Mar. 1, 2022 (JP) 2022-030840

(51) Int. Cl. H01L 27/02

(52) U.S. Cl. CPC H01L 27/0255

(57) ABSTRACT

In the present invention, a second MOSFET comprises: a body region; a drain region extending in the y direction; a first well region formed away from the drain region in the x direction; a gate electrode formed on a gate insulating film and a field oxide film; a source region formed on the surface of a first well region; an exposed region formed at a position different from the source region in the first well region as viewed from the z direction; a first contact part joined to the source region; a second contact part Schottky-joined to the exposed region; a third contact part joined to the gate electrode; and source wiring that electrically interconnects the first contact part, the second contact part, and the third contact part.

### CROSS-REFERENCE TO RELATED APPLICATIONS

This application is a continuation of, and claims the benefit of priority from International Application No. PCT/JP2023/007193, filed on Feb. 28, 2023, which claims the benefit of priority from Japanese Patent Application No. 2022-030840, filed on Mar. 1, 2022, the entire contents of each of which are incorporated herein by reference.

### BACKGROUND

### 1. Field

The present disclosure relates to a semiconductor device.

### 2. Description of Related Art

A semiconductor device (refer to, for example, Japanese Laid-Open Patent Publication No. 11-68038) including a metal-oxide-semiconductor field-effect transistor (MOSFET) may be used as a protection circuit used for protection from electrostatic discharge (ESD).

### BRIEF DESCRIPTION OF DRAWINGS

FIG. 1 is a circuit diagram showing an exemplary circuit configuration of a semiconductor integrated circuit including a first embodiment of a protection circuit.

FIG. 2 is a schematic plan view showing an exemplary planar structure of a second MOSFET in the protection circuit.

FIG. 3 is a schematic cross-sectional view showing the cross-sectional structure of the second MOSFET taken along lines F3-F3 shown in FIG. 2.

FIG. 4 is a circuit diagram showing the second MOSFET and a parasitic element.

FIG. 5 is a schematic plan view showing the planar structure of a comparative MOSFET.

FIG. 6 is a schematic cross-sectional view showing the cross-sectional structure of the comparative MOSFET taken along lines F6-F6 shown in FIG. 5.

FIG. 7 is a circuit diagram showing the comparative MOSFET and a parasitic element.

FIG. 8 is a characteristic diagram showing I-V characteristics of the second MOSFET and the comparative MOSFET.

FIG. 9 is a schematic plan view showing an exemplary planar structure of a first modified example of the second MOSFET.

FIG. 10 is a schematic plan view showing an exemplary planar structure of a second modified example of the second MOSFET.

FIG. 11 is a schematic plan view showing an exemplary planar structure of a third modified example of the second MOSFET.

FIG. 12 is a schematic plan view showing an exemplary planar structure of a fourth modified example of the second MOSFET.

FIG. 13 is a schematic plan view showing an exemplary planar structure of a fifth modified example of the second MOSFET.

FIG. 14 is a schematic plan view showing an exemplary planar structure of a sixth modified example of the second MOSFET.

FIG. 15 is a schematic plan view showing an exemplary planar structure of a seventh modified example of the second MOSFET.

FIG. 16 is a schematic plan view showing an exemplary planar structure of an eighth modified example of the second MOSFET.

FIG. 17 is a schematic plan view showing an exemplary planar structure of a protection circuit in a second embodiment.

FIG. 18 is a schematic cross-sectional view showing a cross-sectional structure of the protection circuit in FIG. 17.

FIG. 19 is a schematic plan view showing an exemplary planar structure of a first modified example of a third MOSFET.

FIG. 20 is a schematic plan view showing an exemplary planar structure of a second modified example of the third MOSFET.

### DETAILED DESCRIPTION

Embodiments of a semiconductor device according to the present disclosure will be described below with reference to the drawings. In the drawings, components may not be drawn to scale for simplicity and clarity of illustration. In a cross-sectional view, hatching may be omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

### First Embodiment

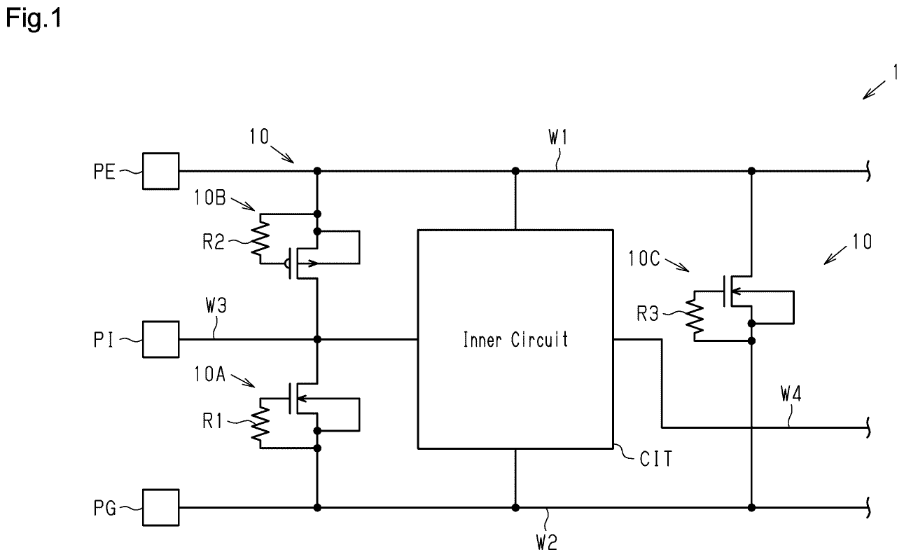

The structure of a first embodiment of a semiconductor device, which is embodied as a protection circuit 10, will now be described with reference to FIGS. 1 to 4.

As shown in FIG. 1, the protection circuit 10 is, for example, connected to a semiconductor integrated circuit (LSI) 1, which includes an inner circuit CIT on which transistors are formed, to protect the inner circuit CIT from ESD. The semiconductor integrated circuit 1 has a package structure in which the inner circuit CIT is encapsulated with an encapsulation resin, which is not shown. That is, the encapsulation resin encapsulates the protection circuit 10 together with the inner circuit CIT.

The semiconductor integrated circuit 1 includes a power electrode PE, a ground electrode PG, and an input electrode PI connected to the inner circuit CIT. The electrodes PE, PG, and PI are exposed from the encapsulation resin.

The power electrode PE supplies power voltage to the inner circuit CIT. The ground electrode PG is used to connect the inner circuit CIT to ground. The input electrode PI is electrically connected to an external control circuit to input a signal to the inner circuit CIT.

The semiconductor integrated circuit 1 includes a first wire W1 connected to the power electrode PE, a second wire W2 connected to the ground electrode PG, and a third wire W3 connected to the input electrode PI. The wires W1 to W3 are connected to the inner circuit CIT. The semiconductor integrated circuit 1 further includes a fourth wire W4 transmitting a signal output from the inner circuit CIT.

The protection circuit 10 protects the inner circuit CIT from a current caused by ESD acting to flow into the inner circuit CIT through the power electrode PE and the input electrode PI. The protection circuit 10 includes a first MOSFET 10A connected between the input electrode PI and the ground electrode PG, a second MOSFET 10B connected between the power electrode PE and the input electrode PI, and a third MOSFET 10C connected between the power electrode PE and the ground electrode PG.

In other words, the first MOSFET 10A is arranged between the third wire W3 and the second wire W2. The second MOSFET 10B is arranged between the first wire W1 and the third wire W3. The third MOSFET 10C is arranged between the first wire W1 and the second wire W2. The first MOSFET 10A and the third MOSFET 10C are each an n-type MOSFET. The second MOSFET 10B is a p-type MOSFET.

The connection configuration of the MOSFETs 10A to 10C will now be described.

The first MOSFET 10A and the second MOSFET 10B are connected in series. More specifically, the source of the second MOSFET 10B is connected to the power electrode PE (first wire W1). The drain of the second MOSFET 10B is connected to the input electrode PI (third wire W3). The drain of the first MOSFET 10A is connected to the input electrode PI (third wire W3). The source of the first MOSFET 10A is connected to the ground electrode PG (second wire W2). In the first embodiment, the source of the second MOSFET 10B is connected to the first wire W1 between the power electrode PE and the inner circuit CIT. The drain of the first MOSFET 10A and the drain of the second MOSFET 10B are connected to the third wire W3 between the input electrode PI and the inner circuit CIT. The source of the first MOSFET 10A is connected to the second wire W2 between the ground electrode PG and the inner circuit CIT.

The third MOSFET 10C is located at a side of the inner circuit CIT opposite from the first MOSFET 10A and the second MOSFET 10B. The drain of the third MOSFET 10C is connected to the first wire W1. The source of the third MOSFET 10C is connected to the second wire W2.

The gate of the first MOSFET 10A is connected to the source of the first MOSFET 10A by a first resistive element R1. The gate of the second MOSFET 10B is connected to the source of the second MOSFET 10B by a second resistive element R2. The gate of the third MOSFET 10C is connected to the source of the third MOSFET 10C by a third resistive element R3. More specifically, the first to third resistive elements R1 to R3 are electrically connected between the gate and the source of the first to third MOSFETs 10A to 10C, respectively. In addition, in the first embodiment, the first to third MOSFETs 10A to 10C each have a back gate connected to the source of the respective first to third MOSFETs 10A to 10C.

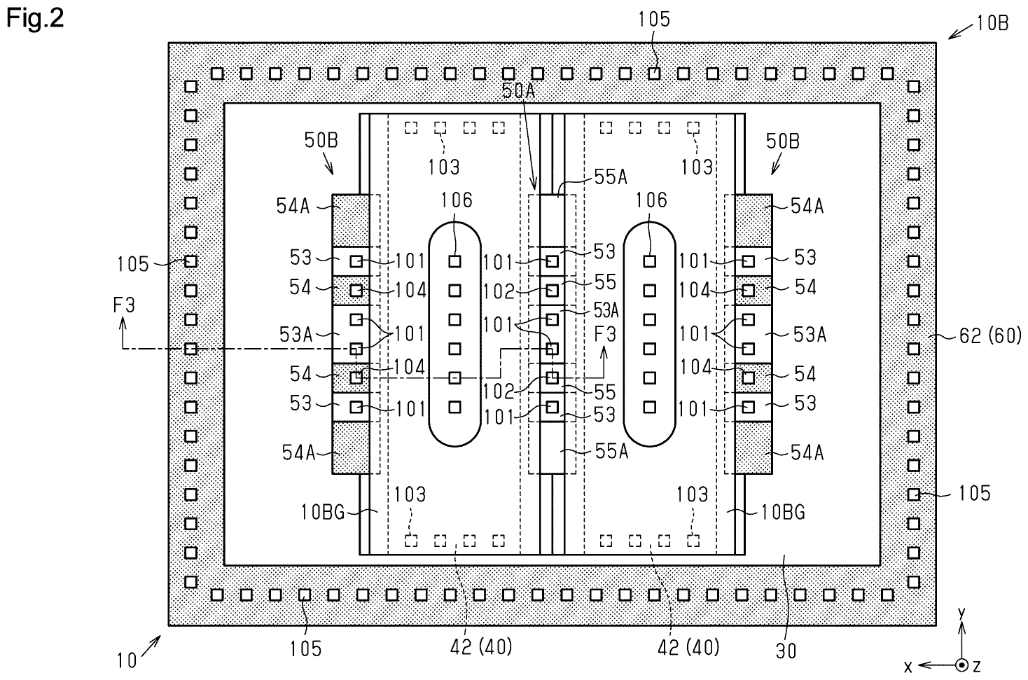

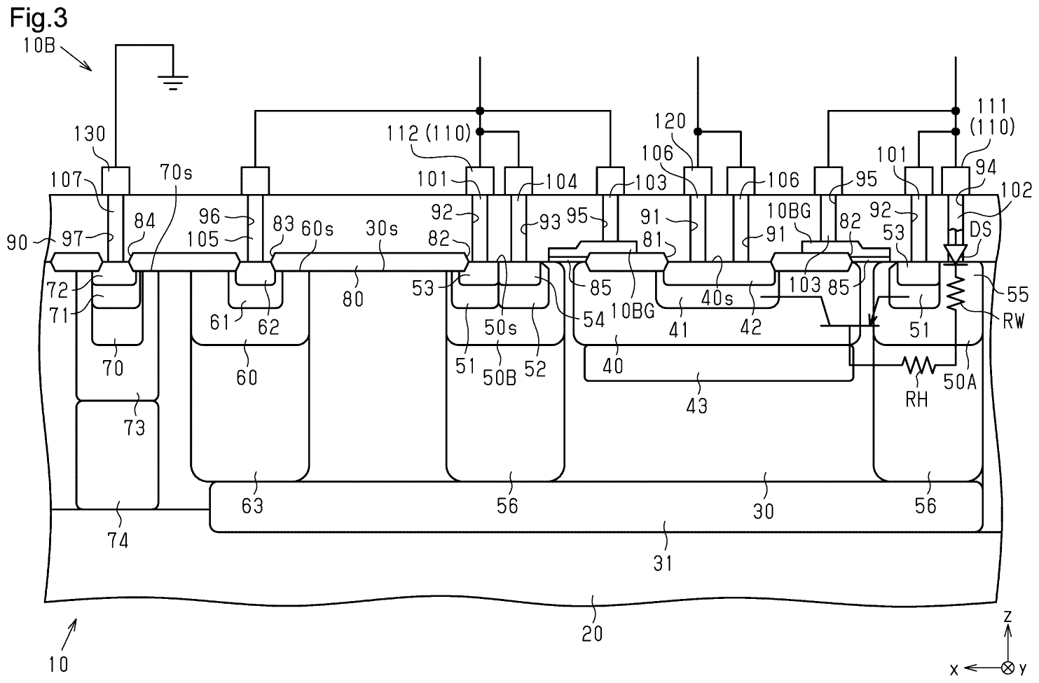

The structure of the first to third MOSFETs 10A to 10C will now be described in detail with reference to FIGS. 2 and 3. FIG. 2 shows an example of a planar structure of the second MOSFET 10B, which is a part of the protection circuit 10. FIG. 3 shows an example of a cross-sectional structure of the second MOSFET 10B. For the sake of illustration, FIG. 2 does not show an element separation region 70 and its surroundings, which will be described later. In FIG. 3, for the sake of illustration, a source region 53 and a highly-doped region 54, which will be described later, are shown next to each other. Also, the source region 53 and an exposed region 55, which will be described later, are shown next to each other.

As shown in FIG. 3, the protection circuit 10 includes a semiconductor substrate 20 and a semiconductor layer 30 of a first conductivity type (in the first embodiment, n-type) formed on the semiconductor substrate 20.

The semiconductor substrate 20 is formed from, for example, a material containing silicon (Si). In the first embodiment, the semiconductor substrate 20 is an Si substrate. The semiconductor substrate 20 has a thickness that is, for example, in a range of 100 μm to 700 μm. In the first embodiment, the semiconductor substrate 20 has a dopant concentration that is in a range of 1×10¹³ cm⁻³ to 1×10¹⁶ cm⁻³.

The semiconductor layer 30 is, for example, a layer epitaxially growing from the semiconductor substrate 20 and formed from a material including, for example, Si. The semiconductor layer 30 has a thickness that is, for example, in a range of 2 μm to 20 μm. In the first embodiment, the semiconductor layer 30 has a dopant concentration that is in a range of 1×10¹⁴ cm⁻³ to 1×10¹⁶ cm⁻³.

In the first embodiment, the thickness-wise direction of the semiconductor layer 30 is referred to as the “z-direction.” A view of the protection circuit 10 in the z-direction is referred to as “plan view.” In this case, “plan view” includes the meaning of “view in the thickness-wise direction of the semiconductor layer 30.” Two directions orthogonal to each other and orthogonal to the z-direction are referred to as the “x-direction” and the “y-direction.” In the first embodiment, the y-direction corresponds to a “first direction.” The x-direction corresponds to a “second direction.”

The second MOSFET 10B is formed on the semiconductor layer 30 formed on the semiconductor substrate 20. Although not shown, the first MOSFET 10A and the third MOSFET 10C are also formed on the semiconductor layer 30. The first MOSFET 10A and the third MOSFET 10C have the same structure as the second MOSFET 10B except that the conductivity type is inverted. Thus, while the configuration of the second MOSFET 10B will be described below, the configurations of the first MOSFET 10A and the third MOSFET 10C will not be described.

The semiconductor layer 30 includes a surface 30s in which a body region 40 of a second conductivity type (in the first embodiment, p-type), a first well region 50A of the first conductivity type (in the first embodiment, n-type), and a second well region 50B of the first conductivity type, which is the same as the first well region 50A, are arranged. Additionally, a ring-shaped region 60 and the element separation region 70 of the second conductivity type (in the first embodiment, p-type) are arrange in the surface 30s of the semiconductor layer 30. The ring-shaped region 60 surrounds the body region 40, the first well region 50A, and the second well region 50B. The element separation region 70 surrounds the ring-shaped region 60. The ring-shaped region 60 is a semiconductor region of the first conductivity type (in the first embodiment, n-type).

In plan view, the portion surrounded by the element separation region 70 defines an element formation region of the second MOSFET 10B. In other words, the element formation region is a region in which the body region 40, the first well region 50A, and the second well region 50B are formed. In the first embodiment, the element formation region includes the ring-shaped region 60. The element formation region may include multiple body regions 40, multiple first well regions 50A, and multiple second well regions 50B. As shown in FIG. 2, in the first embodiment, two body regions 40, one first well region 50A, and two second well regions 50B are arranged next to one another in the element formation region. The direction in which the body regions 40, the first well region 50A, and the second well regions 50B are arranged is referred to as the x-direction. In other words, the two body regions 40, the one first well region 50A, and the two second well regions 50B are separated from each other and arranged in the second direction. Thus, the semiconductor layer 30 is located between each body region 40 and the first well region 50A and between the body region 40 and the corresponding second well region 50B in the x-direction. In the first embodiment, the first well region 50A is located in a center of the element formation region in the second direction (x-direction). The two second well regions 50B are separately arranged at opposite sides of the first well region 50A in the x-direction. Each body region 40 is arranged between the first well region 50A and the corresponding one of the second well regions 50B in the x-direction. In other words, the two second well regions 50B are located at opposite ends of the element formation region in the second direction (x-direction). The first well region 50A and the second well region 50B are arranged at opposite sides of the body region 40 in the second direction (x-direction). The number of body regions 40, the number of first well regions 50A, and the number of second well regions 50B in the element formation region may be changed in any manner.

The body regions 40 extend in the y-direction. More specifically, the body regions 40 extend in the first direction orthogonal to the arrangement direction (x-direction, second direction) of the body regions 40, the first well region 50A, and the second well regions 50B in plan view. In the first embodiment, each body region 40 has a larger width-wise dimension (dimension in x-direction) than the first well region 50A. The body region 40 has a higher dopant concentration than the semiconductor layer 30. In the first embodiment, the dopant concentration of the body region 40 is in a range of 1×10¹⁵ cm⁻³ to 1×10¹⁷ cm⁻³.

The body region 40 has a surface 40s in which an intermediate body region 41 of the second conductivity type (in the first embodiment, p-type) is formed. The intermediate body region 41 is separated from the semiconductor layer 30 located around the body region 40. The intermediate body region 41 extends in the y-direction. The intermediate body region 41 has a higher dopant concentration than the body region 40. In the first embodiment, the dopant concentration of the intermediate body region 41 is in a range of 1×10¹⁷ cm⁻³ to 1×10¹⁹ cm⁻³.

A drain region 42 of the second conductivity type (in the first embodiment, p⁺-type) is formed in a surface of the intermediate body region 41. In other words, the drain region 42 is formed in the surface 40s of the body region 40. In the same manner as the intermediate body region 41, the drain region 42 is separated from the semiconductor layer 30 located around the body region 40. The drain region 42 extends in the y-direction (first direction). The drain region 42 has a higher dopant concentration than the intermediate body region 41. Therefore, the dopant concentration of the drain region 42 is higher than the dopant concentration of the body region 40. In the first embodiment, the dopant concentration of the drain region 42 is in a range of 1×10¹⁸ cm⁻³ to 1×10²⁰ cm⁻³. Thus, in the first embodiment, as in the intermediate body region 41 and the drain region 42, the second MOSFET 10B includes a source region formed through double diffusion such that a p-type dopant is diffused at a first concentration and a second concentration that is higher than the first concentration.

In the element formation region, an embedded body region 43 is formed adjacent to the body region 40 in the z-direction. The embedded body region 43 is located closer, in the z-direction, to the semiconductor substrate 20 than the body region 40 is. The embedded body region 43 has a higher dopant concentration than the semiconductor layer 30. In the first embodiment, the dopant concentration of the embedded body region 43 is in a range of 1×10¹⁵ cm⁻³ to 1×10¹⁷ cm⁻³.

The first well region 50A extends in the y-direction. The first well region 50A has a higher dopant concentration than the semiconductor layer 30. In an example, the first well region 50A has the same dopant concentration as the body region 40. In the first embodiment, the dopant concentration of the first well region 50A is in a range of 1×10¹⁵ cm⁻³ to 1×10¹⁷ cm⁻³.

The first well region 50A has a surface 50s in which a source intermediate region 51 of the second conductivity type (in the first embodiment, p-type) is formed. The first well region 50A includes multiple source intermediate regions 51. The source intermediate regions 51 are separated from each other in the y-direction. Each source intermediate region 51 has a higher dopant concentration than the first well region 50A. In the first embodiment, the dopant concentration of the source intermediate region 51 is in a range of 1×10¹⁷ cm⁻³ to 1×10¹⁹ cm⁻³.

In plan view, each exposed region 55 is formed in the first well region 50A at a position differing from each source region 53. In plan view, the exposed region 55 is formed in the first well region 50A at a position differing from the source intermediate region 51 and the source region 53. Thus, the exposed region 55 is a region where the first well region 50A is exposed in the surface 30s of the semiconductor layer 30. That is, the exposed region 55 is part of the first well region 50A. Therefore, the dopant concentration of the exposed region 55 is equal to the dopant concentration of the first well region 50A and is in a range of 1×10¹⁵ cm⁻³ to 1×10¹⁷ cm⁻³. In other words, the dopant concentration of the exposed region 55 is lower than the dopant concentration of the source intermediate region 51.

The source region 53 of the second conductivity type (in the first embodiment, p⁺-type) is formed in a surface of each source intermediate region 51. In other words, the source region 53 is formed in the surface 50s of the first well region 50A. The source region 53 has a higher dopant concentration than the source intermediate region 51. In the first embodiment, the dopant concentration of the source region 53 is in a range of 1×10¹⁸ cm⁻³ to 1×10²⁰ cm⁻³. Thus, in the first embodiment, as in the source intermediate region 51 and the source region 53, the second MOSFET 10B includes a source region formed through double diffusion such that an n-type dopant is diffused at a third concentration and a fourth concentration that is higher than the third concentration.

The second well region 50B extends in the y-direction. The second well region 50B has the same dopant concentration as the first well region 50A. In the same manner as the well region 50A, the source intermediate region 51 and the source region 53 are formed in the surface 50s of the second well region 50B. An intermediate region 52 of the first conductivity type (in the first embodiment, n-type) is formed in the surface 50s of the second well region 50B. In the second well region 50B, the source intermediate region 51 and the intermediate region 52 are formed next to each other in the y-direction (first direction). Multiple source intermediate regions 51 and multiple intermediate regions 52 are arranged.

The intermediate regions 52 are separated from each other in the y-direction. Each intermediate region 52 has a higher dopant concentration than the second well region 50B. In the first embodiment, the dopant concentration of the intermediate region 52 is in a range of 1×10¹⁷ cm⁻³ to 1×10¹⁹ cm⁻³. The intermediate region 52 has the same dopant concentration as the source intermediate region 51.

The highly-doped region 54 of the first conductivity type (in the first embodiment, n⁺-type) is formed in a surface of each intermediate region 52. In other words, the highly-doped region 54 is formed in the surface 50s of the second well region 50B. The source region 53 and the highly-doped region 54 are formed next to each other in the y-direction. The highly-doped region 54 has a higher dopant concentration than the intermediate region 52. Thus, the dopant concentration of the highly-doped region 54 is higher than the dopant concentration of the second well region 50B. In the first embodiment, the dopant concentration of the highly-doped region 54 is in a range of 1×10¹⁸ cm⁻³ to 1×10²⁰ cm⁻³. The highly-doped region 54 has the same dopant concentration as the source region 53.

As described above, in the first well region 50A, the highly-doped region 54 and the intermediate region 52 are not formed, whereas the source intermediate region 51, the source region 53, and the exposed region 55 are formed. In the first embodiment, the source region 53 and the exposed region 55 are formed next to each other in the first direction (x-direction). In plan view, the source intermediate region 51 is formed in the same position as the source region 53 but not in the same position as the exposed region 55. In the second well region 50B, the exposed region 55 is not formed, whereas the source intermediate region 51, the intermediate region 52, the source region 53, and the highly-doped region 54 are formed. In the first embodiment, the source region 53 and the highly-doped region 54 are formed next to each other in the first direction (x-direction). The source intermediate region 51 and the intermediate region 52 are formed next to each other in the first direction (x-direction).

High voltage regions 56 of the first conductivity type (in the first embodiment, n-type) are formed as a deep well region in the semiconductor layer 30 at the same position as the well regions 50A and 50B. Each high voltage region 56 extends in the y-direction. The high voltage region 56 has a higher dopant concentration than the semiconductor layer 30. In the first embodiment, the dopant concentration of the high voltage region 56 is in a range of 1×10¹⁵ cm⁻³ to 1×10¹⁷ cm⁻³.

The ring-shaped region 60 is formed separately from the body region 40, the first well region 50A, and the second well region 50B in the x-direction and the y-direction. The ring-shaped region 60 has a higher dopant concentration than the semiconductor layer 30. In the first embodiment, the dopant concentration of the ring-shaped region 60 is in a range of 1×10¹⁵ cm⁻³ to 1×10¹⁷ cm⁻³. In an example, the ring-shaped region 60 has the same dopant concentration as the well regions 50A and 50B.

The ring-shaped region 60 includes a surface 60s in which a ring-side intermediate region 61 of the first conductivity type (in the first embodiment, n-type) is formed. In the first embodiment, the ring-side intermediate region 61 is ring-shaped in plan view in the same manner as the ring-shaped region 60. The ring-side intermediate region 61 has a higher dopant concentration than the ring-shaped region 60. In the first embodiment, the dopant concentration of the ring-side intermediate region 61 is in a range of 1×10¹⁷ cm⁻³ to 1×10¹⁹ cm⁻³. In an example, the ring-side intermediate region 61 has the same dopant concentration as the intermediate region 52.

A ring-side highly-doped region 62 of the first conductivity type (in the first embodiment, n⁺-type) is formed in a surface of the ring-side intermediate region 61. In the first embodiment, the ring-side highly-doped region 62 is ring-shaped in plan view in the same manner as the ring-shaped region 60 and the ring-side intermediate region 61. The ring-side highly-doped region 62 has a higher dopant concentration than the ring-side intermediate region 61. In the first embodiment, the dopant concentration of the ring-side highly-doped region 62 is in a range of 1×10¹⁸ cm⁻³ to 1×10²⁰ cm⁻³. In an example, the ring-side highly-doped region 62 has the same dopant concentration as the highly-doped region 54.

A ring-side high voltage region 63 of the first conductivity type (in the first embodiment, n-type) is formed as a deep well region in the semiconductor layer 30 at the same position as the ring-shaped region 60. The ring-side high voltage region 63 is ring-shaped in plan view in the same manner as the ring-shaped region 60. The ring-side high voltage region 63 has a higher dopant concentration than the semiconductor layer 30. In the first embodiment, the dopant concentration of the ring-side high voltage region 63 is in a range of 1×10¹⁵ cm⁻³ to 1×10¹⁷ cm⁻³. In an example, the ring-side high voltage region 63 has the same dopant concentration as the high voltage region 56.

An embedded layer 31 of the first conductivity type (in the first embodiment, n-type) is formed in the element formation region. The embedded layer 31 is formed separately from the well regions 50A and 50B in the z-direction. The embedded layer 31 is formed over the entirety of the element formation region in plan view. The embedded layer 31 is formed in a boundary between the semiconductor substrate 20 and the semiconductor layer 30. The embedded layer 31 has a higher dopant concentration than the semiconductor layer 30. In the first embodiment, the dopant concentration of the embedded layer 31 is in a range of 1×10¹⁶ cm⁻³ to 1×10²⁰ cm⁻³.

The element separation region 70 is formed separately from the ring-shaped region 60 in the x-direction and the y-direction. The element separation region 70 has a higher dopant concentration than the semiconductor layer 30. In the first embodiment, the dopant concentration of the element separation region 70 is in a range of 1×10¹⁵ cm⁻³ to 1×10¹⁷ cm⁻³. In an example, the element separation region 70 has the same dopant concentration as the body region 40.

The element separation region 70 has a surface 70s in which an element-separation-side intermediate region 71 of the second conductivity type (in the first embodiment, p-type) is formed. In the first embodiment, the element-separation-side intermediate region 71 is ring-shaped in plan view in the same manner as the element separation region 70. The element-separation-side intermediate region 71 has a higher dopant concentration than the element separation region 70. In the first embodiment, the dopant concentration of the element-separation-side intermediate region 71 is in a range of 1×10¹⁷ cm⁻³ to 1×10¹⁹ cm⁻³. In an example, the element-separation-side intermediate region 71 has the same dopant concentration as the intermediate region 52.

An element-separation-side highly-doped region 72 of the second conductivity type (in the first embodiment, p⁺-type) is formed in a surface of the element-separation-side intermediate region 71. In the first embodiment, the element-separation-side highly-doped region 72 is ring-shaped in plan view in the same manner as the element separation region 70 and the element-separation-side intermediate region 71. The element-separation-side highly-doped region 72 has a higher dopant concentration than the element-separation-side intermediate region 71. In the first embodiment, the dopant concentration of the element-separation-side highly-doped region 72 is in a range of 1×10¹⁸ cm⁻³ to 1×10²⁰ cm⁻³. In an example, the element-separation-side highly-doped region 72 has the same dopant concentration as the highly-doped region 54.

An element-separation-side high voltage region 73 of the second conductivity type (in the first embodiment, p-type) is formed as a deep well region in the semiconductor layer 30 at the same position as the element separation region 70. The element-separation-side high voltage region 73 is ring-shaped in plan view in the same manner as the element separation region 70. The element-separation-side high voltage region 73 has a higher dopant concentration than the semiconductor layer 30. In the first embodiment, the dopant concentration of the element-separation-side high voltage region 73 is in a range of 1×10¹⁵ cm⁻³ to 1×10¹⁷ cm⁻³.

An element-separation-side embedded layer 74 is formed in the semiconductor layer 30 to overlap the element separation region 70 in plan view. The element-separation-side embedded layer 74 is ring-shaped in plan view in the same manner as the element separation region 70. The element-separation-side embedded layer 74 is located closer to the semiconductor substrate 20 than the element-separation-side high voltage region 73 is. The element-separation-side embedded layer 74 has a higher dopant concentration than the element separation region 70. In the first embodiment, the dopant concentration of the element-separation-side embedded layer 74 is in a range of 1×10¹⁶ cm⁻³ to 1×10²⁰ cm⁻³.

In the first embodiment, the element separation is achieved by local oxidation of silicon (LOCOS). In this configuration, a field oxide film 80 is formed so as to be embedded in the surface 30s of the semiconductor layer 30. The field oxide film 80 is formed from a material including, for example, SiO₂, as an insulation layer for element separation. The field oxide film 80 includes first to fourth openings 81 to 84.

The first opening 81 exposes the drain region 42. Multiple first openings 81 are arranged and separated from each other in the y-direction. Thus, the field oxide film 80 partially covers the drain region 42.

The second opening 82 exposes portions from peripheral edges of each body region 40 to peripheral edges of the well regions 50A and 50B that are located adjacent to the body region 40 in the x-direction. In other words, the field oxide film 80 covers the surface 40s of the body region 40. Multiple second openings 82 are arranged and separated from each other in the y-direction. More specifically, the second openings 82 partially expose each of the source region 53, the highly-doped region 54, and the exposed region 55. Thus, the field oxide film 80 covers a remaining part of each of the source region 53, the highly-doped region 54, and the exposed region 55.

A gate insulation film 85 is formed on the semiconductor layer 30 between the body region 40 and each of the well regions 50A and 50B in the x-direction. In other words, the field oxide film 80 is formed on a portion of the surface 40s of the body region 40 between the gate insulation film 85 and the drain region 42 in the x-direction. The gate insulation film 85 is formed from a material including, for example, SiO₂.

A gate electrode 10BG is formed on the gate insulation film 85. The gate electrode 10BG is formed from the gate insulation film 85 to a portion of the field oxide film 80. In other words, the gate electrode 10BG is formed on the gate insulation film 85 and the field oxide film 80. The gate electrode 10BG is formed from, for example, a material containing at least one of polysilicon, cobalt (Co), hafnium (Hf), zirconium (Zr), aluminum (Al), titanium (Ti), tantalum (Ta), and molybdenum (Mo).

The third opening 83 exposes the ring-side highly-doped region 62 of the ring-shaped region 60. Multiple third openings 83 are formed and separated from each other in a peripheral direction of the ring-side highly-doped region 62. The field oxide film 80 covers the ring-shaped region 60, the ring-side intermediate region 61, and the semiconductor layer 30 between the ring-shaped region 60 and each of the well regions 50A and 50B in the x-direction. In addition, the field oxide film 80 partially covers the ring-side highly-doped region 62.

The fourth opening 84 exposes the element-separation-side highly-doped region 72 of the element separation region 70. Multiple fourth openings 84 are formed and separated from each other in a peripheral direction of the element-separation-side highly-doped region 72. The field oxide film 80 covers the element separation region 70, the element-separation-side intermediate region 71, and the semiconductor layer 30 between the ring-shaped region 60 and the element separation region 70 in the x-direction. In addition, the field oxide film 80 partially covers the element-separation-side highly-doped region 72.

The protection circuit 10 includes an insulation layer 90 covering the field oxide film 80 and the gate electrode 10BG. The insulation layer 90 is formed from a material including, for example, SiO₂. The insulation layer 90 includes first to seventh openings 91 to 97 extending through the insulation layer 90 in the z-direction.

The first opening 91 is formed in the first opening 81 in plan view. The first opening 91 is formed to overlap the drain region 42 in plan view. Thus, the drain region 42 is exposed from the insulation layer 90 through the first opening 91. The insulation layer 90 is formed in the first opening 81.

The second to fourth openings 92 to 94 are formed in the second opening 82 in plan view. The insulation layer 90 is formed in the second opening 82.

The second opening 92 is formed to overlap the source region 53 in plan view. Thus, the source region 53 is exposed from the insulation layer 90 through the second opening 92.

The third opening 93 is formed to overlap the highly-doped region 54 in plan view. Thus, the highly-doped region 54 is exposed from the insulation layer 90 through the third opening 93.

The fourth opening 94 is formed to overlap the exposed region 55 in plan view. Thus, the exposed region 55 is exposed from the insulation layer 90 through the fourth opening 94.

The fifth opening 95 is formed to overlap the gate electrode 10BG in plan view. Thus, the gate electrode 10BG is partially exposed from the insulation layer 90 through the fifth opening 95.

The sixth opening 96 is formed in the third opening 83 in plan view. The sixth opening 96 is formed to overlap the ring-side highly-doped region 62 in plan view. Thus, the ring-side highly-doped region 62 is exposed from the insulation layer 90 through the sixth opening 96.

The seventh opening 97 is formed in the fourth opening 84 in plan view. The seventh opening 97 is formed to overlap the element-separation-side highly-doped region 72 in plan view. Thus, the element-separation-side highly-doped region 72 is exposed from the insulation layer 90 through the seventh opening 97.

The protection circuit 10 includes first to seventh contacts 101 to 107, each of which is a contact bonded to a semiconductor region. The first to seventh contacts 101 to 107 are formed from a conducive material including, for example, at least one of copper (Cu), Al, and Ti. The first to seventh contacts 101 to 107 extend through the insulation layer 90.

The first contact 101 is bonded to the source region 53. More specifically, the first contact 101 is formed of a conductive material filling the second opening 92. The first contact 101 is in ohmic contact with the source region 53. In the first embodiment, the first contact 101 corresponds to a “source contact.”

The second contact 102 forms a Schottky junction with the exposed region 55. More specifically, the second contact 102 is formed of a conductive material filling the fourth opening 94. Since the dopant concentration of the exposed region 55 is low, a Schottky barrier is formed in a portion where the exposed region 55 contacts the second contact 102.

The third contact 103 is bonded to the gate electrode 10BG. More specifically, the third contact 103 is formed of a conductive material filling the fifth opening 95. The third contact 103 is in ohmic contact with the gate electrode 10BG. In the first embodiment, the third contact 103 corresponds to a “gate contact.”

The fourth contact 104 is bonded to the highly-doped region 54. More specifically, the fourth contact 104 is formed of a conductive material filling the third opening 93. The fourth contact 104 is in ohmic contact with the highly-doped region 54.

The fifth contact 105 is bonded to the ring-side highly-doped region 62. More specifically, the fifth contact 105 is formed of a conductive material filling the sixth opening 96. The fifth contact 105 is in ohmic contact with the ring-side highly-doped region 62.

The sixth contact 106 is bonded to the drain region 42. More specifically, the sixth contact 106 is formed of a conductive material filling the first opening 91. The sixth contact 106 is in ohmic contact with the drain region 42.

The seventh contact 107 is bonded to the element-separation-side highly-doped region 72. More specifically, the seventh contact 107 is formed of a conductive material filling the seventh opening 97. The seventh contact 107 is in ohmic contact with the element-separation-side highly-doped region 72.

A source interconnect 110, a drain interconnect 120, and an outermost interconnect 130 are formed on the insulation layer 90. The interconnects 110, 120, and 130 are formed from a material including, for example, at least one of Cu, Al, and Ti. In the first embodiment, the source interconnect 110 corresponds to an “interconnect.”

The source interconnect 110 serves as the source of the second MOSFET 10B. The source interconnect 110 includes an inner source interconnect 111 and an outer source interconnect 112. The inner source interconnect 111 is electrically connected to the outer source interconnect 112.

The inner source interconnect 111 electrically connects the first contact 101, the second contact 102, and the third contact 103 to each other. Thus, the source region 53, the exposed region 55, and the gate electrode 10BG are electrically connected to each other by the inner source interconnect 111, the first contact 101, the second contact 102, and the third contact 103. The inner source interconnect 111 is in ohmic contact with the first contact 101, the second contact 102, and the third contact 103.

The outer source interconnect 112 electrically connects the first contact 101 and the third contact 103 to each other. The outer source interconnect 112 is also electrically connected to the fourth contact 104. The outer source interconnect 112 is also electrically connected to the fifth contact 105. Thus, the source region 53, the gate electrode 10BG, the highly-doped region 54, and the ring-side highly-doped region 62 are electrically connected to each other by the outer source interconnect 112, the first contact 101, the third contact 103, the fourth contact 104, and the fifth contact 105. The outer source interconnect 112 is in ohmic contact with the first contact 101, the third contact 103, the fourth contact 104, and the fifth contact 105.

The drain interconnect 120 is connected to the sixth contact 106. Thus, the drain interconnect 120 is electrically connected to the drain region 42. The drain interconnect 120 serves as the drain of the second MOSFET 10B. The drain interconnect 120 is in ohmic contact with the sixth contact 106.

The outermost interconnect 130 is connected to the seventh contact 107. Thus, the outermost interconnect 130 is electrically connected to the element-separation-side highly-doped region 72. The outermost interconnect 130 is also connected to ground. Thus, the element separation region 70 is electrically connected to ground through the seventh contact 107 and the outermost interconnect 130. The outermost interconnect 130 is in ohmic contact with the seventh contact 107.

The arrangement of the source regions 53, the highly-doped regions 54, and the exposed regions 55 and the arrangement of the contacts will now be described with reference to FIG. 2. In FIG. 2, the highly-doped regions 54 and the ring-side highly-doped region 62 are indicated by dots for the sake of clarity.

As shown in FIG. 2, multiple (in the first embodiment, three) source regions 53 and multiple (in the first embodiment, four) highly-doped regions 54 are formed in each second well region 50B. In the second well region 50B, the source regions 53 and the highly-doped regions 54 are alternately arranged in the first direction (y-direction). In the first embodiment, the highly-doped regions 54 are formed at opposite ends of the second well region 50B in the y-direction, and the source region 53 is formed in a center of the second well region 50B in the y-direction. The highly-doped regions 54 located at opposite ends of the second well region 50B in the y-direction are each referred to as an “end highly-doped region 54A.” The source region 53 located in the center of the second well region 50B in the y-direction is referred to as a “central source region 53A.”

The end highly-doped region 54A has a larger dimension in the y-direction than the highly-doped region 54, which is located closer to the center in the y-direction than the end highly-doped region 54A is. The end highly-doped region 54A is equal in dimension in the x-direction to the other highly-doped regions 54. Thus, in plan view, the end highly-doped region 54A is greater in area than each of the other highly-doped regions 54.

As shown in FIG. 2, the highly-doped regions 54 (end highly-doped regions 54A) formed in each second well region 50B are symmetrically arranged with respect to the x-direction and the y-direction. In the first embodiment, the highly-doped regions 54 (end highly-doped regions 54A) are point-symmetrically arranged about the center of the element formation region (the center in both the x-direction and the y-direction).

The central source region 53A has a larger dimension in the y-direction than the source region 53, which is located closer to one of the ends in the y-direction than the central source region 53A is. The central source region 53A is equal in dimension in the x-direction to the other source regions 53. Thus, in plan view, the central source region 53A is greater in area than each of the other source regions 53.

The first contact 101 is bonded to each of the central source region 53A and the other source regions 53 in each second well region 50B. In the first embodiment, two first contacts 101 are bonded to the central source region 53A. The two first contacts 101 are aligned with each other in the x-direction and separated from each other in the y-direction.

The fourth contact 104 is not bonded to the end highly-doped region 54A. The fourth contact 104 is bonded to the highly-doped region 54 other than the end highly-doped region 54A in each second well region 50B. In the first embodiment, two fourth contacts 104 are separately bonded to two highly-doped regions 54 in the second well region 50B. Therefore, the second MOSFET 10B includes four fourth contacts 104.

In the first well region 50A, multiple (in the first embodiment, three) source regions 53 and multiple (in the first embodiment, four) exposed regions 55 are formed. In the first well region 50A, the exposed regions 55 and the source regions 53 are arranged in the first direction (y-direction). In the first embodiment, the source regions 53 and the exposed regions 55 are alternately arranged in the first well region 50A in the y-direction. In the first embodiment, the source regions 53 in the first well region 50A are aligned with the source regions 53 in the second well region 50B in the first direction (y-direction). The exposed regions 55 in the first well region 50A are aligned with the highly-doped regions 54 in the second well region 50B in the first direction (y-direction). Two exposed regions 55 located at opposite ends of the first well region 50A in the y-direction are each referred to as an “end exposed region 55A.”

In the first well region 50A, the source regions 53 include a central source region 53A in the same manner as the second well regions 50B.

The end exposed region 55A has a larger dimension in the y-direction than the other exposed regions 55 in the first well region 50A. The end exposed region 55A is equal in dimension in the x-direction to the other exposed regions 55. Thus, in plan view, the end exposed region 55A is greater in area than each of the other exposed regions 55.

In the first embodiment, the exposed regions 55 (end exposed regions 55A) formed in the first well region 50A are symmetrically arranged with respect to the x-direction. The exposed regions 55 (end exposed regions 55A) are formed in only the first well region 50A, which is located in the center of the element formation region in the x-direction. Thus, the exposed regions 55 (end exposed regions 55A) are symmetrically arranged with respect to the x-direction and the y-direction. The exposed regions 55 (end exposed regions 55A) are formed adjacent to the source region 53 (central source region 53A) in the x-direction. More specifically, in each second well region 50B, the distances between the exposed regions 55 (end exposed regions 55A) and the source regions 53 (central source region 53A) are the same.

As described above, in the first well region 50A, the exposed regions 55 are formed instead of the highly-doped regions 54. Thus, in the second MOSFET 10B, the area of the highly-doped regions 54 is decreased as compared to a structure in which the second well region 50B is formed instead of the first well region 50A. In other words, in the second MOSFET 10B, the number of highly-doped regions 54 is decreased as compared to a structure in which the second well region 50B is formed instead of the first well region 50A.

The first contact 101 is bonded to each of the central source region 53A and other source regions 53 in the first well region 50A. In the first embodiment, two first contacts 101 are bonded to the central source region 53A in the same manner as the second well regions 50B.

The second contact 102 is not bonded to the end exposed region 55A. The second contact 102 is bonded to (forms Schottky junction with) the exposed regions 55 other than the end exposed region 55A in the first well region 50A. In the first embodiment, two second contacts 102 are separately bonded to two exposed regions 55 in the first well region 50A. Thus, the second MOSFET 10B includes two second contacts 102. Thus, in the first embodiment, the number of second contacts 102 forming a Schottky junction with the exposed regions 55 is less than the number of fourth contacts 104 in ohmic contact with the highly-doped regions 54.

As shown in FIG. 2, multiple third contacts 103 are bonded to the gate electrode 10BG (refer to FIG. 3) and arranged on opposite ends of the element formation region in the y-direction.

Multiple fifth contacts 105, bonded to the ring-side highly-doped region 62, are arranged separately from each other in a peripheral direction of the ring-side highly-doped region 62.

Multiple sixth contacts 106 are bonded to the drain region 42 and arranged closer to the center of the drain region 42 than to the opposite ends of the drain region 42 in the y-direction. The sixth contacts 106 are aligned with each other in the x-direction and separated from each other in the y-direction. The number of third contacts 103, the number of fifth contacts 105, and the number of sixth contacts 106 may be changed in any manner.

In the second MOSFET 10B configured as described above, as shown in FIG. 3, a parasitic PNP transistor is formed between the back gate and the source of the second MOSFET 10B. The parasitic PNP transistor has emitter electrically connected to the source region 53, collector electrically connected to the drain region 42, and base electrically connected to the exposed region 55 or the highly-doped region 54.

### Operation

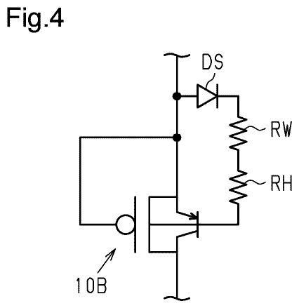

The operation of the first embodiment will now be described with reference to FIGS. 4 to 8.

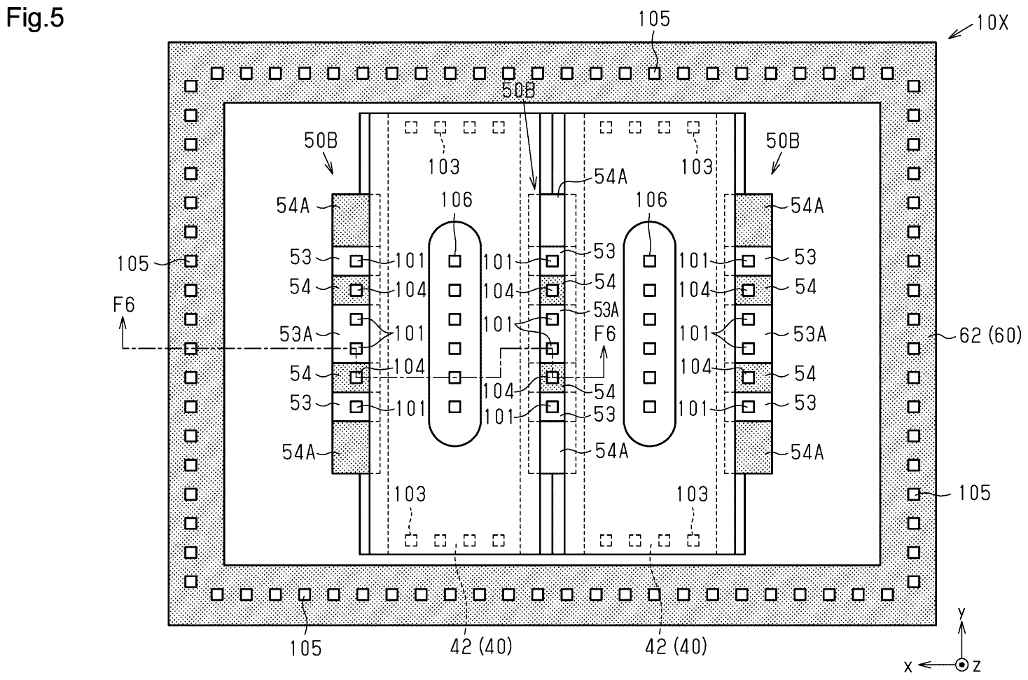

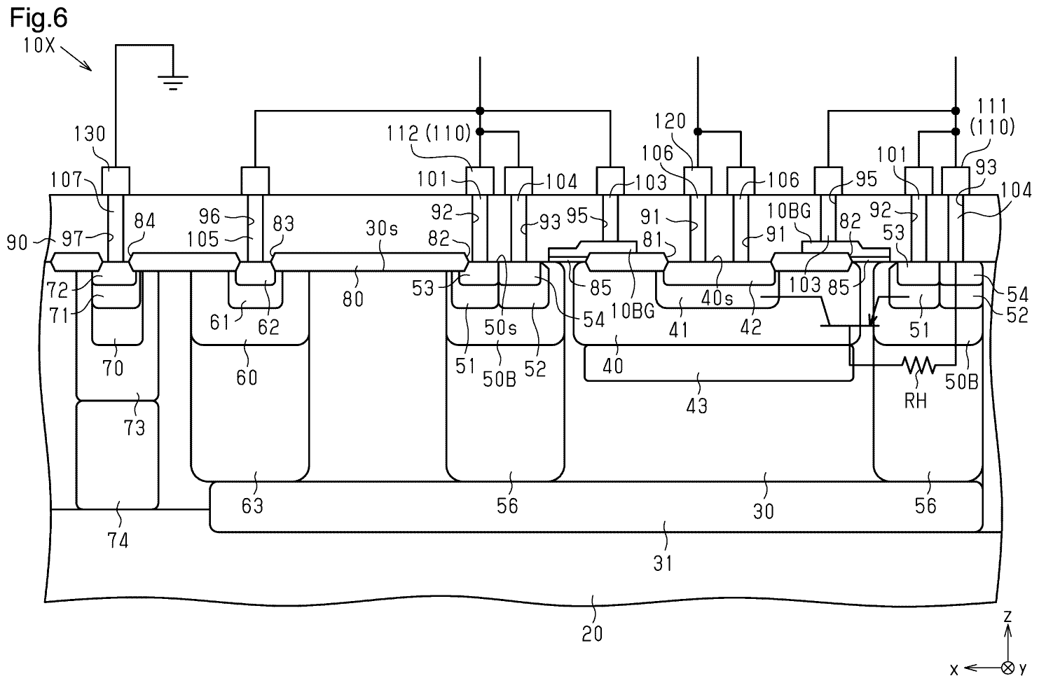

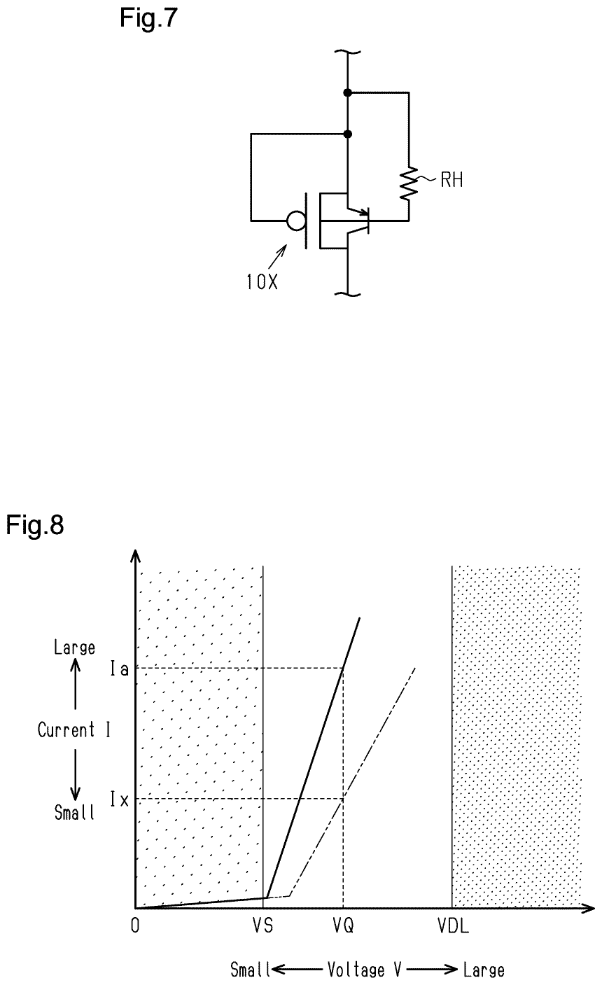

FIG. 5 shows a planar structure of a MOSFET (hereafter, referred to as “comparative MOSFET 10X”) in a protection circuit of a comparative example. FIG. 6 is a cross-sectional structure of the comparative MOSFET 10X. FIG. 7 is an equivalent circuit diagram in the comparative MOSFET 10X and the fourth contact 104. FIG. 8 is a characteristic diagram showing I-V characteristics of the protection circuit in the comparative example and the protection circuit 10 in the first embodiment. In the description below, the same reference characters are given to the components commonly used in the comparative MOSFET 10X and the second MOSFET 10B in the protection circuit 10 of the first embodiment. Such components will not be described in detail. In FIG. 8, the solid line shows the I-V characteristic of the second MOSFET 10B of the first embodiment. In FIG. 8, the double-dashed line shows the I-V characteristic of the comparative MOSFET 10X.

As shown in FIGS. 5 and 6, the comparative MOSFET 10X differs from the second MOSFET 10B of the first embodiment in the arrangement of the highly-doped regions 54 and in that the exposed regions 55 are not formed. More specifically, in the comparative MOSFET 10X, the second well region 50B is formed instead of the first well region 50A. The first contact 101 is in ohmic contact with the source region 53. The fourth contact 104 is in ohmic contact with the highly-doped region 54.

The comparative MOSFET 10X has a back gate electrically connected to the source of the comparative MOSFET 10X through the second well region 50B, the intermediate region 52, the highly-doped region 54, and the fourth contact 104. Thus, as shown in FIG. 7, in the comparative MOSFET 10X, the base-emitter of the parasitic PNP transistor has substantially only a resistance component RH of a deep portion of the second well region 50B.

FIG. 4 is an equivalent circuit diagram in the second MOSFET 10B and the second contact 102. In the second MOSFET 10B, the base of the parasitic PNP transistor is connected to the highly-doped region 54 and the exposed region 55 (refer to FIG. 3). Thus, the base-emitter voltage is increased as compared to the comparative MOSFET 10X. More specifically, as shown in FIG. 4, at the location where the base is connected to the exposed region 55, between the base and the emitter, the parasitic PNP transistor of the second MOSFET 10B has a resistance component RH of a deep portion of the first well region 50A (portion of the first well region 50A located close to the semiconductor substrate 20 in the z-direction), a resistance component RW of a shallow portion of the first well region 50A (exposed region 55) (portion of the first well region 50A located close to the surface 30s of the semiconductor layer 30 in the z-direction), and a diode component DS due to a Schottky junction of the exposed region 55 with the second contact 102. Thus, the second MOSFET 10B of the first embodiment, in which the base is connected to the exposed region 55, has a larger base-emitter voltage than the comparative MOSFET 10X.

In the second MOSFET 10B, when the collector-emitter voltage of the parasitic PNP is increased, a Zenner breakdown occurs due to an electric field caused by a reverse biased p-n junction between the base and the collector. As a result, electron-hole pairs are generated and collected on the base and the collector. This generates a base-collector current. The current then generates a base-emitter voltage. Thus, the majority carrier conduction between the emitter and the collector becomes dominant and allows a large amount of the collector current to flow between the collector and the emitter. In addition, when the base-emitter voltage is increased, the potential barrier between the emitter and the base is decreased. This facilitates movement of the p-type majority carrier from the emitter to the collector. This results in an increase in the collector current, which decreases the on-resistance of the second MOSFET 10B.

A voltage V between the first wire W1 and the second wire W2 (refer to FIG. 1) varies in accordance with ESD. The protection circuit 10 protects the inner circuit CIT (refer to FIG. 1) from the varying voltage V. More specifically, as shown in FIG. 8, the protection circuit 10 needs to be actuated so that the voltage V is less than a first voltage value VDL, which is the lower limit value from which the inner circuit CIT starts to break. In addition, in order to avoid actuation of the protection circuit 10 in the operating voltage range of the inner circuit CIT, the protection circuit 10 needs to be actuated at a voltage higher than a second voltage value VS, which is higher than the upper limit value of the operating voltage range. Thus, the protection circuit 10 needs to be actuated in a voltage range that is greater than the second voltage value VS and less than the first voltage value VDL. As shown in FIG. 8, the I-V characteristic indicates that as the voltage V increases, a current I increases in the above-described voltage range in each of the second MOSFET 10B and the comparative MOSFET 10X.

As described above, the parasitic PNP transistor of the second MOSFET 10B has a higher base-emitter voltage than the parasitic PNP transistor of the comparative MOSFET 10X. Thus, the second MOSFET 10B has a smaller on-resistance than the comparative MOSFET 10X. Accordingly, as shown in FIG. 8 with the I-V characteristic, the current of the second MOSFET 10B is increased at a higher rate than the current of the comparative MOSFET 10X. For example, when ESD causes a voltage VQ in the above-described voltage range to be applied to the second MOSFET 10B and the comparative MOSFET 10X, a current Ia flowing to the second MOSFET 10B is greater than a current Ix flowing to the comparative MOSFET 10X. This inhibits the current flowing to the inner circuit CIT in the second MOSFET 10B more than in the comparative MOSFET 10X, and thus the inner circuit CIT is protected. Accordingly, as compared to the comparative MOSFET 10X, the second MOSFET 10B demonstrates a higher resistance to ESD when a human body model (HBM) is used in ESD test. Here, the HBM is a test that simulates a case in which static electricity is discharged from a human body to a device. The HBM complies with, for example, ANSI/ESDA/JEDEC JS-001-2017.

An example of results of ESD withstand voltage will be described below. In the following description, a positive ESD withstand voltage is an ESD withstand voltage when a voltage is applied to the positive side. A negative ESD withstand voltage is an ESD withstand voltage when a voltage is applied to the negative side.

In an ESD test using the HBM, the comparative MOSFET 10X has a positive ESD withstand voltage of 5000 V and a negative ESD withstand voltage of −12000 V. The second MOSFET 10B has a positive ESD withstand voltage of 5750 V and a negative ESD withstand voltage of −6750 V.

The results of the ESD withstand voltage obtained by the HBM show that in the comparative MOSFET 10X, the absolute value of the negative ESD withstand voltage is significantly greater than the absolute value of the positive ESD withstand voltage. That is, in the comparative MOSFET 10X, the negative ESD withstand voltage is excessively high and is imbalanced with the positive ESD withstand voltage.

In the second MOSFET 10B, the positive ESD withstand voltage obtained by the HBM is greater than that of the comparative MOSFET 10X. In the second MOSFET 10B, the negative ESD withstand voltage obtained by the HBM is lower than that of the comparative MOSFET 10X. Therefore, in the second MOSFET 10B, the difference in the absolute value between the positive ESD withstand voltage and the negative ESD withstand voltage obtained by the HBM is small. That is, in the second MOSFET 10B, the negative ESD withstand voltage is in good balance with the positive ESD withstand voltage.

As in the second MOSFET 10B, the positive ESD withstand voltage is increased by decreasing the highly-doped region 54, that is, by forming the exposed region 55 forming a Schottky junction with the second contact 102. When the highly-doped region 54 is deceased, the negative ESD withstand voltage is decreased. However, the negative ESD withstand voltage is originally sufficiently high, and the absolute value of the negative ESD withstand voltage is still greater than the positive ESD withstand voltage. This limits adverse effects on the ESD withstand voltage.

### Advantages

The first embodiment obtains the following advantages.

(1-1) The protection circuit 10 including the first to third MOSFETs 10A, 10B, and 10C includes the semiconductor layer 30 of a first conductivity type, the body region 40 of a second conductivity type formed on the surface 30s of the semiconductor layer 30, the drain region 42 of the second conductivity type formed on the surface 40s of the body region 40 and separated from the semiconductor layer 30 located around the body region 40, the drain region 42 extending in the y-direction, the first well region 50A of the first conductivity type formed on the surface 30s of the semiconductor layer 30 and separated from the drain region 42 in the x-direction, the gate insulation film 85 formed on the semiconductor layer 30 between the first well region 50A and the body region 40, the field oxide film 80 formed on a portion of the surface 40s of the body region 40 between the gate insulation film 85 and the drain region 42, the gate electrode 10BG formed on the gate insulation film 85 and the field oxide film 80, the source region 53 of the second conductivity type formed on the surface 50s of the first well region 50A, the exposed region 55 formed in the first well region 50A at a position differing from the source region 53 in the z-direction, the first contact 101 bonded to the source region 53, the second contact 102 forming a Schottky junction with the exposed region 55, the third contact 103 bonded to the gate electrode 10BG, and the source interconnect 110 electrically connecting the first contact 101, the second contact 102, and the third contact 103 to each other.

In this structure, the base-emitter voltage of the parasitic PNP transistor is increased by a Schottky barrier (diode component) between the exposed region 55 and the second contact 102, a resistance component of the first well region 50A, and a resistance component of the exposed region 55. This increases the current flowing to the second MOSFET 10B caused by ESD. The first MOSFET 10A and the third MOSFET 10C have the same configuration as the second MOSFET 10B. Thus, the current flowing to the first and third MOSFETs 10A and 10C caused by ESD is increased. This increases the resistance of the protection circuit 10 to ESD.

(1-2) The protection circuit 10 further includes the second well region 50B, in which the exposed region 55 is not formed, including the source region 53 and the highly-doped region 54 formed in a position differing from the source region 53 in plan view, and the fourth contact 104 bonded to the highly-doped region 54. The highly-doped region 54 has a higher dopant concentration than the exposed region 55. The source interconnect 110 is electrically connected to the fourth contact 104.

In this structure, the positive ESD withstand voltage is increased by, for example, increasing the number of exposed regions 55 in the second MOSFET 10B and decreasing the number of highly-doped regions 54. The negative ESD withstand voltage is increased by, for example, decreasing the number of exposed regions 55 and increasing the number of highly-doped regions 54. As described above, the second MOSFET 10B includes the exposed region 55 and the highly-doped region 54 so that the positive ESD withstand voltage and the negative ESD withstand voltage are adjusted. This allows the second MOSFET 10B to have a good balance between the positive ESD withstand voltage and the negative ESD withstand voltage. Thus, an ESD withstand voltage necessary for the protection circuit 10 is readily obtained.

(1-3) The highly-doped regions 54 are symmetrically arranged with respect to the x-direction and the y-direction.

In this structure, for example, when a collector current, caused by the parasitic PNP transistor of the second MOSFET 10B, flows from the ring-shaped region 60 and the source regions 53 to the drain regions 42, variations in the collector current flowing to the drain regions 42 are limited.

(1-4) The protection circuit 10 includes the intermediate region 52, which is a semiconductor region of the first conductivity type formed on the surface 50s of the second well region 50B and having a dopant concentration that is greater than the dopant concentration of the second well region 50B and less than the dopant concentration of the highly-doped region 54. The highly-doped region 54 is formed on the surface of the intermediate region 52. The exposed region 55 is a portion of the surface 50s of the second well region 50B differing from the intermediate region 52.

In this configuration, the exposed region 55 has a lower dopant concentration than the intermediate region 52. This increases the Schottky barrier between the exposed region 55 and the second contact 102. In addition, the intermediate region 52 limits concentration of an electric field on the gate electrode 10BG.

### Modified Example of First Embodiment

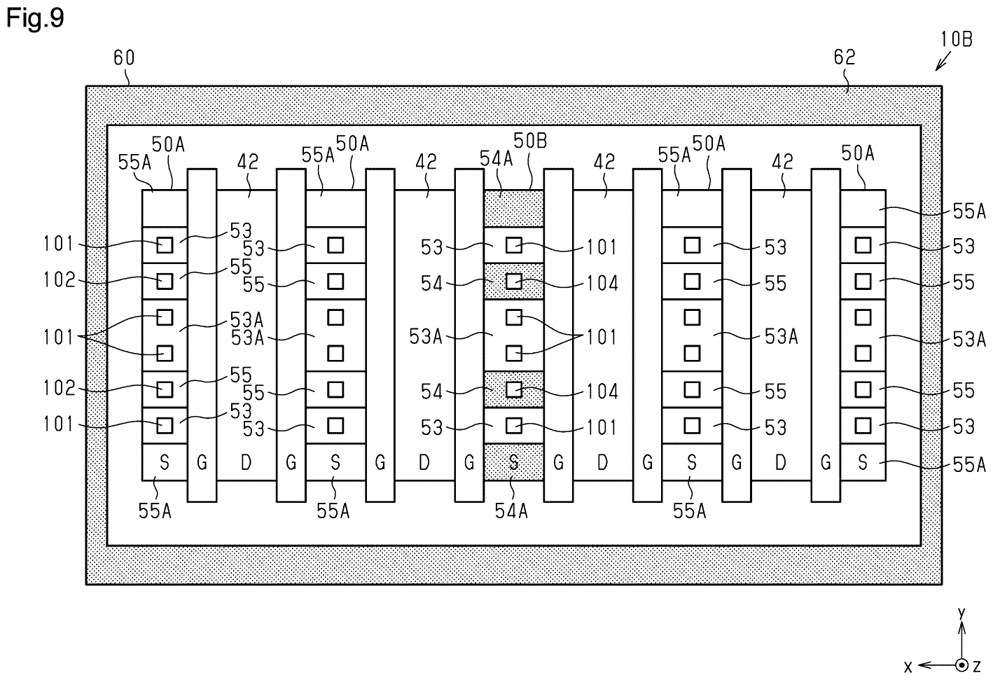

The first embodiment may be modified as follows. The modified examples described below may be combined with one another as long as there is no technical inconsistency. In FIGS. 9 to 15, for the sake of illustration, the first well region 50A, the second well region 50B, the drain region 42, the source region 53, the highly-doped region 54, the exposed region 55, and the ring-shaped region 60 are only shown as semiconductor regions.

The configuration of the element separation in the protection circuit 10 may be changed in any manner. In an example, shallow trench isolation (STI) may be used as the element separation.

At least one of the embedded layer 31, the embedded body region 43, the high voltage region 56, the ring-side high voltage region 63, the element-separation-side high voltage region 73, and the element-separation-side embedded layer 74 may be omitted from at least one of the first to third MOSFETs 10A to 10C.

The highly-doped regions 54 may be asymmetrically arranged with respect to the x-direction or the y-direction.

The exposed regions 55 may be asymmetrically arranged with respect to the x-direction or the y-direction.

The number of source regions 53 and the number of drain regions 42 may be changed in any manner. In an example, as shown in FIGS. 9 to 15, the protection circuit 10 may include four body regions 40 (drain regions 42) and at least one of the first well region 50A and the second well region 50B. In the protection circuit 10 shown in FIGS. 9 to 15, the first well region 50A or the second well region 50B is formed in the center and the opposite ends of the element formation region in the x-direction. The drain region 42 is arranged alternately with the first well region 50A or the second well region 50B in the x-direction. In the x-direction, the gate electrode 10BG is formed between the drain region 42 and the first well region 50A or the second well region 50B that is located adjacent to the drain region 42 in the x-direction. In the examples shown, in plan view, the gate electrode 10BG has the form of a strip extending in the y-direction. As shown in FIGS. 9 to 15, the drain region 42 is denoted by “D.” The well regions 50A and 50B are denoted by “S.” The gate electrode 10BG is denoted by “G.”

### Modified Examples of Well Region

The arrangement of the highly-doped regions 54 and the exposed regions 55 may be changed in any manner. The arrangement of the highly-doped regions 54 and the exposed regions 55 may be changed, for example, as shown in first to fourth modified examples shown in FIGS. 9 to 12. In the first to fourth modified examples, the arrangement of the drain regions 42 and the sixth contacts 106 (refer to FIG. 2) is the same as that of the drain regions 42 and the sixth contacts 106 of the first embodiment. In the first to fourth modified examples, the arrangement of the ring-side highly-doped regions 62 and the fifth contacts 105 (refer to FIG. 2) is the same as that of the ring-side highly-doped regions 62 and the fifth contacts 105 of the first embodiment. Thus, the drain regions 42 and the sixth contacts 106 will not be described below. FIGS. 9 to 12 do not show the fifth contacts 105 and the sixth contacts 106.

### First Modified Example

FIG. 9 shows a first modified example in which a single second well region 50B is formed in a center of the element formation region in the second direction (x-direction). Multiple (in the first modified example, four) first well regions 50A are formed. Among the four first well regions 50A, two first well regions 50A are formed at opposite ends of the element formation region in the second direction (x-direction). In the x-direction, the remaining two well regions 50A are formed between the second well region 50B and each of the first well regions 50A that are located at opposite ends of the element formation region in the second direction (x-direction).

Multiple highly-doped regions 54 and multiple source regions 53 are formed in the second well region 50B. In the second well region 50B, the highly-doped regions 54 and the source regions 53 are arranged in the first direction (y-direction). In the example shown in FIG. 9, the highly-doped regions 54 and the source regions 53 are alternately arranged in the second well region 50B in the y-direction.

Multiple source regions 53 and multiple exposed regions 55 are formed in each of the first well regions 50A. The arrangement of the source regions 53 and the exposed regions 55 is the same as the arrangement of the source regions 53 and the exposed regions 55 of the first well region 50A in the first embodiment.

As described above, in the first modified example, the number of first well regions 50A is greater than the number of second well regions 50B. Thus, the total area of the exposed regions 55 is greater than the total area of the highly-doped regions 54. In other words, the number of exposed regions 55 is greater than the number of highly-doped regions 54.

The arrangement of the first contacts 101 and the second contacts 102 in the first well region 50A is the same as the arrangement of the first contacts 101 and the second contacts 102 in the first well region 50A of the first embodiment. The arrangement of the first contacts 101 and the fourth contacts 104 in the second well region 50B is the same as the arrangement of the first contacts 101 and the fourth contacts 104 in the second well region 50B of the first embodiment. Thus, in the first modified example, the number of second contacts 102 is greater than the number of fourth contacts 104.

As shown in FIG. 9, the highly-doped regions 54 (end highly-doped regions 54A) are symmetrically arranged with respect to the y-direction. Since the second well region 50B is formed in the center of the element formation region in the x-direction, the highly-doped regions 54 (end highly-doped regions 54A) are symmetrically arranged with respect to the x-direction and the y-direction. The exposed regions 55 (end exposed regions 55A) are symmetrically arranged with respect to the x-direction and the y-direction.

In the first modified example, one to three of the four first well regions 50A may be changed to a second well region 50B. In an example, the second well regions 50B are formed in a center of the element formation region in the x-direction and at opposite ends of the element formation region in the x-direction. The first well region 50A may be formed between the center and each of the opposite ends of the element formation region in the x-direction.

With the structure of the first modified example, the number of second contacts 102 forming a Schottky junction with the exposed regions 55 is greater than the number of fourth contacts 104 bonded to the highly-doped regions 54. This improves the positive ESD withstand voltage of the second MOSFET 10B.

### Second Modified Example

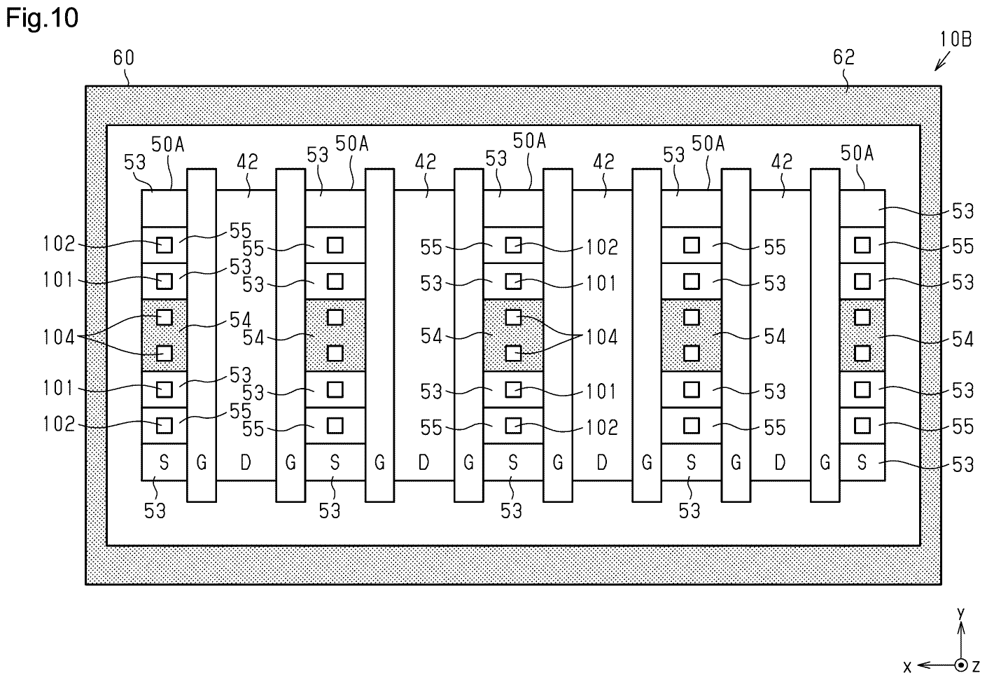

FIG. 10 shows a second modified example in which the highly-doped region 54 is formed in the first well region 50A. In plan view, the highly-doped region 54 is formed in the first well region 50A at a position differing from the source region 53 and the exposed region 55. In the second modified example, the second well region 50B is not formed.

The highly-doped region 54 of the first well region 50A is formed in a center of each first well region 50A in the y-direction. More specifically, the first well region 50A includes multiple (in the second modified example, four) source regions 53, multiple (in the second modified example, two) exposed regions 55, and one highly-doped region 54. The source regions 53 are formed at opposite sides of the highly-doped region 54 in the y-direction and opposite ends of the first well region 50A in the y-direction. The exposed regions 55 are formed between ones of the source regions 53 located adjacent to each other in the y-direction. As shown in FIG. 10, the highly-doped regions 54 are symmetrically arranged with respect to the x-direction. The highly-doped regions 54 are symmetrically arranged with respect to the x-direction and the y-direction. In the second modified example, the exposed regions 55 are greater in number than the highly-doped regions 54 in the first well region 50A. However, the area of the highly-doped region 54 is greater than the area of each exposed region 55 in the first well region 50A. Thus, in the first well region 50A, the total area of the exposed regions 55 is equal to the area of the highly-doped region 54. In the second MOSFET 10B, the second well region 50B (refer to FIG. 9) is not formed, and the first well region 50A is formed. In the second MOSFET 10B, the total area of the exposed regions 55 is equal to the total area of the highly-doped regions 54.

In each first well region 50A, the first contact 101 is bonded to a source region 53 that is located closer to the center of the first well region 50A than to the opposite ends, in the y-direction, of the first well region 50A. The second contact 102 forms a Schottky junction with each exposed region 55. The two fourth contacts 104 are bonded to each highly-doped region 54. That is, each first well region 50A is provided with two second contacts 102 and two fourth contacts 104. Thus, in the second modified example, in the second MOSFET 10B, the second contact 102 is equal in number to the fourth contact 104.

In the second modified example, one to four of the five first well regions 50A may be changed to a second well region 50B. The highly-doped region 54 is formed in a center of the second well region 50B in the y-direction. In addition, multiple (three) highly-doped regions 54 and multiple (three) source regions 53 are alternately arranged in the second well region 50B.

With the structure of the second modified example, the number of second contacts 102 forming a Schottky junction with the exposed regions 55 is equal to the number of fourth contacts 104 bonded to the highly-doped regions 54. Thus, the positive ESD withstand voltage is balanced with the negative ESD withstand voltage in the second MOSFET 10B.

### Third Modified Example

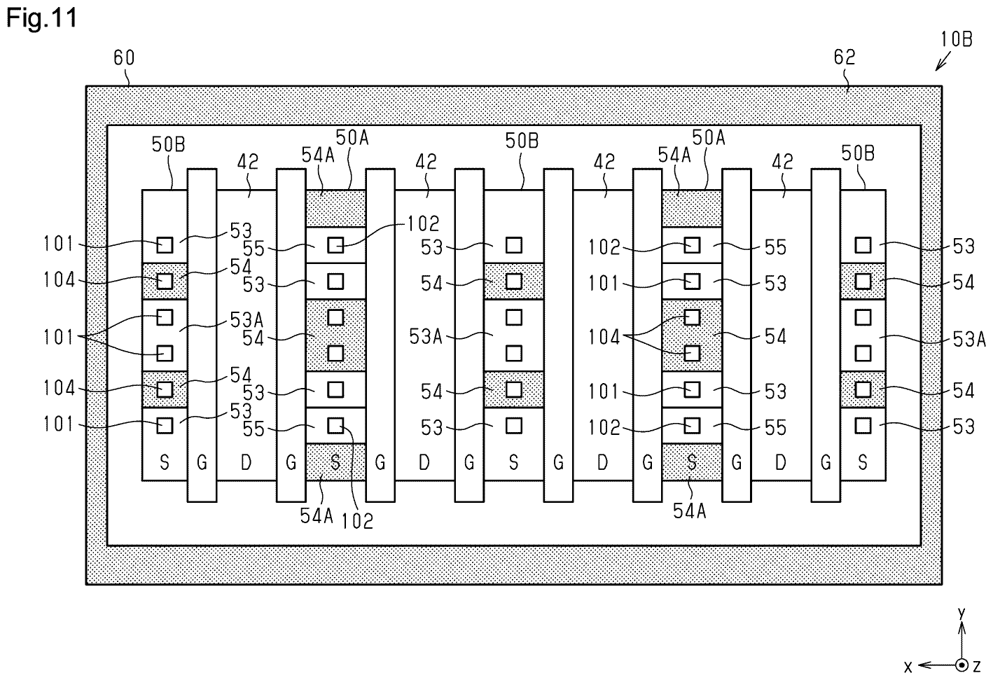

FIG. 11 shows a third modified example in which multiple (in the third modified example, two) first well regions 50A and multiple (in the third modified example, three) second well regions 50B are formed in the element formation region. The second well regions 50B are formed at opposite ends and the center of the element formation region in the second direction (x-direction). The first well regions 50A are formed between ones of the second well regions 50B located adjacent to each other in the second direction (x-direction). That is, the first well regions 50A and the second well regions 50B are alternately arranged in the second direction (x-direction).

In each second well region 50B, two highly-doped regions 54 and three source regions 53 are formed. The highly-doped regions 54 and the source regions 53 are alternately arranged in the first direction (y-direction). The source regions 53 are arranged at the center of the first well region 50A in the y-direction and opposite ends of the first well region 50A in the y-direction. Each source region 53 is greater in area in plan view than each highly-doped region 54. The highly-doped regions 54 are formed, in the y-direction, between the source region 53 located at the center and each of the source regions 53 located at the opposite ends in the y-direction.

In each first well region 50A, three highly-doped regions 54, two source regions 53, and two exposed regions 55 are formed. The source regions 53, the highly-doped regions 54, and the exposed regions 55 are formed next to one another in the y-direction. The highly-doped regions 54 are formed at opposite ends of the first well region 50A in the y-direction and the center of the first well region 50A in the y-direction. Therefore, the highly-doped regions 54 of the first well region 50A and the highly-doped regions 54 of the second well region 50B are located at different positions in the y-direction.

As shown in FIG. 11, the highly-doped regions 54 (end highly-doped regions 54A) are symmetrically arranged with respect to the x-direction and the y-direction. The exposed regions 55 are also symmetrically arranged with respect to the x-direction and the y-direction.

In the third modified example, in the second MOSFET 10B, the total area of the highly-doped regions 54 (end highly-doped regions 54A) is greater than the total area of the exposed regions 55. In other words, in the second MOSFET 10B, the number of highly-doped regions 54 (end highly-doped region 54A) is greater than the number of exposed regions 55.

In the second well region 50B, each of the source regions 53 may be bonded to two first contacts 101. The central source region 53 is bonded to two first contacts 101. Each of the end source regions 53 is bonded to one first contact 101. The fourth contacts 104 are bonded to each highly-doped region 54. Each of the second well regions 50B is provided with two fourth contacts 104.

In the first well region 50A, the first contact 101 is bonded to each source region 53. The second contact 102 forms a Schottky junction with each exposed region 55. The fourth contact 104 is bonded to each highly-doped region 54. Each of the second well regions 50B is provided with two fourth contacts 104 and two second contacts 102. Thus, in the second MOSFET 10B, the fourth contact 104 is greater in number than the second contact 102.

In the structure of the third modified example, when a collector current, caused by the parasitic PNP transistor of the second MOSFET 10B, flows from the ring-shaped region 60 and the source regions 53 to the drain regions 42, variations in the collector current flowing to the drain regions 42 are limited.

In addition, the number of fourth contacts 104 bonded to the highly-doped regions 54 is greater than the number of second contacts 102 forming a Schottky junction with the exposed regions 55. This improves the negative ESD withstand voltage of the second MOSFET 10B.

### Fourth Modified Example

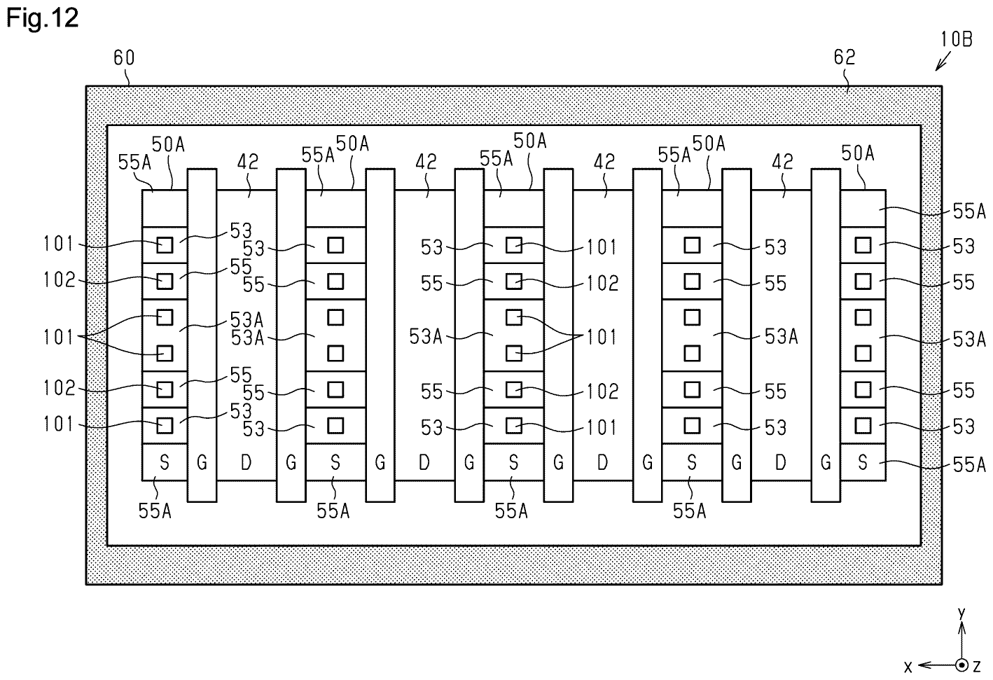

FIG. 12 shows a fourth modified example in which the second well region 50B is not formed in the element formation region. That is, five first well regions 50A are formed in the element formation region.

In each first well region 50A, multiple (in the fourth modified example, three) source regions 53 and multiple (in the fourth modified example, four) exposed regions 55 are formed. The source regions 53 and the exposed regions 55 are alternately arranged in the first direction (y-direction). One source region 53 is formed at the center of the first well region 50A. The exposed regions 55 (end exposed regions 55A) are formed at opposite ends of the center source region 53. In the example shown in FIG. 12, the exposed regions 55 are symmetrically arranged with respect to the x-direction and the y-direction. In the fourth modified example, for example, the arrangement of the contacts in each first well region 50A is the same as the arrangement of the contacts in the first well region 50A of the first embodiment. The structure of the fourth modified example further increases the positive ESD withstand voltage of the second MOSFET 10B.

### Modified Examples of Ring-Shaped Region

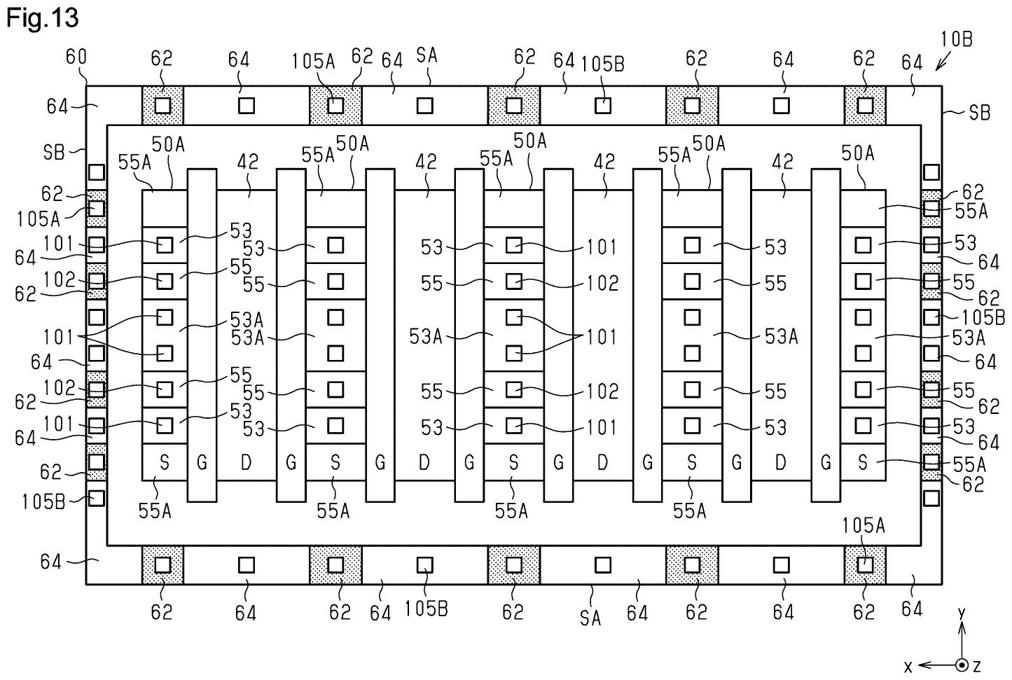

The arrangement of the ring-side highly-doped region 62 may be changed in any manner. In an example, the arrangement may be changed, for example, as in fifth to eighth modified examples shown in FIGS. 13 to 16. In the fifth to seventh modified examples, the structure of the well regions 50A and 50B is the same as that in the fourth modified example. Thus, the well regions 50A and 50B will not be described in detail.

### Fifth Modified Example

As shown in FIG. 13, multiple ring-side highly-doped regions 62 are separated from each other and arranged in a peripheral direction of the ring-shaped region 60. The ring-side intermediate regions 61 (refer to FIG. 3) are not formed between ones of the ring-side highly-doped regions 62 located adjacent to each other in the peripheral direction of the ring-shaped region 60. Instead, the ring-side intermediate regions 61 are formed in the same position as the ring-side highly-doped regions 62 in plan view. Thus, a ring-side exposed region 64 is formed between ones of the ring-side highly-doped regions 62 located adjacent to each other in the peripheral direction of the ring-shaped region 60 to expose the ring-shaped region 60. Thus, multiple ring-side exposed regions 64 are formed. The ring-side highly-doped regions 62 and the ring-side exposed regions 64 are alternately arranged in the peripheral direction of the ring-shaped region 60.

The ring-shaped region 60 is rectangular in plan view. The ring-shaped region 60 includes two sides SA separated in the y-direction and two sides SB separated in the x-direction. The two sides SA extend in the x-direction. In other words, the two sides SA extend in an arrangement direction of the drain regions 42 and the well regions 50A and 50B. The two sides SB extend in the y-direction. In other words, the two sides SB extend in a direction in which the drain regions 42 and the well regions 50A and 50B extend.

In each side SA, multiple (in the fifth modified example, five) ring-side highly-doped regions 62 are formed. The ring-side highly-doped regions 62 are opposed to the respective first well regions 50A in the y-direction. The ring-side exposed regions 64 are formed between ones of the ring-side highly-doped regions 62 located adjacent to each other in the direction in which the sides SA extend (x-direction). In the example shown in FIG. 13, the ring-side highly-doped regions 62 and the ring-side exposed regions 64 are alternately arranged in the direction in which the sides SA extend. Thus, the ring-side exposed regions 64 are opposed to the respective drain regions 42 in the y-direction. The ring-side exposed regions 64 are also opposed to the gate electrodes 10BG in the y-direction.

In each side SB, multiple (in the fifth modified example, four) ring-side highly-doped regions 62 are formed. The ring-side highly-doped regions 62 are opposed, in the second direction (x-direction), to the first well regions 50A that are located at opposite ends of the element formation region in the second direction (x-direction). The ring-side highly-doped regions 62 are arranged in each side SB and separated from each other in the y-direction. Thus, multiple ring-side exposed regions 64 are formed in each side SB. The ring-side exposed regions 64 include ring-side exposed regions that are opposed, in the second direction (x-direction), to the first well regions 50A located at opposite ends of the element formation region in the second direction (x-direction). The ring-side exposed regions 64 further include ring-side exposed regions that are located on each side SB at a position differing from the first well region 50A in the y-direction. In the fifth modified example, the ring-side exposed regions 64 are formed at four corners of the ring-shaped region 60.

As shown in FIG. 13, in the fifth modified example, in each side SA, each ring-side exposed region 64 is greater in area than each ring-side highly-doped region 62. In addition, the total area of the ring-side exposed regions 64 in each side SB is greater than the total area of the ring-side highly-doped regions 62. Thus, in the second MOSFET 10B, the total area of the ring-side exposed regions 64 is greater than the total area of the ring-side highly-doped regions 62.

A ring-side first contact 105A is bonded to each ring-side highly-doped region 62. A ring-side second contact 105B forms a Schottky junction with each ring-side exposed region 64. In the example shown, the number of ring-side second contacts 105B is greater than the number of ring-side first contacts 105A.

With the structure of the fifth modified example, the number of ring-side second contacts 105B forming a Schottky junction with the ring-side exposed regions 64 is greater than the number of ring-side first contacts 105A bonded to the ring-side highly-doped regions 62. This improves the positive ESD withstand voltage of the second MOSFET 10B.

The number of ring-side highly-doped regions 62 may be changed in any manner. Also, the number of ring-side first contacts 105A and the number of ring-side second contacts 105B may be changed in any manner. In an example, the ring-side first contacts 105A are equal in number to the ring-side second contacts 105B. In an example, the ring-side second contacts 105B may be fewer than the ring-side first contacts 105A.

### Sixth Modified Example

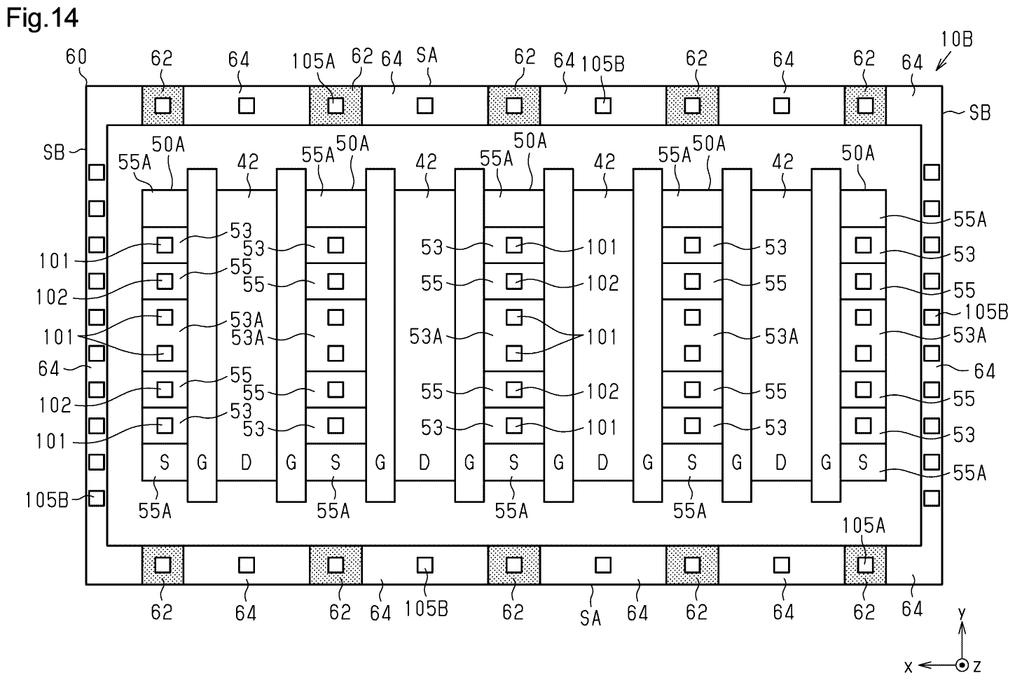

As shown in FIG. 14, multiple ring-side highly-doped regions 62 and multiple ring-side exposed regions 64 are formed in the ring-shaped region 60. The arrangement of the ring-side highly-doped regions 62 and the ring-side exposed regions 64 differs from that of the fifth modified example. The arrangement of the ring-side highly-doped regions 62 and the ring-side exposed regions 64 in each side SA is the same as that of the fifth modified example.

The ring-side highly-doped regions 62 are not formed in the sides SB. That is, the sides SB are formed of the ring-side exposed regions 64. Thus, the total area of the ring-side exposed regions 64 is greater than the total area of the ring-side highly-doped regions 62. The difference between the total area of the ring-side exposed regions 64 and the total area of the ring-side highly-doped regions 62 is greater than that of the fifth modified example.

In the example shown, a ring-side first contact 105A is bonded to each ring-side highly-doped region 62. A ring-side second contact 105B forms a Schottky junction with each ring-side exposed region 64. In the sixth modified example, the number of ring-side second contacts 105B is greater than the number of ring-side first contacts 105A. In the sixth modified example, the number of ring-side second contacts 105B is greater than the number of ring-side second contacts 105B in the fifth modified example. With the structure of the sixth modified example, the positive ESD withstand voltage is further increased as compared to the fifth modified example.

### Seventh Modified Example

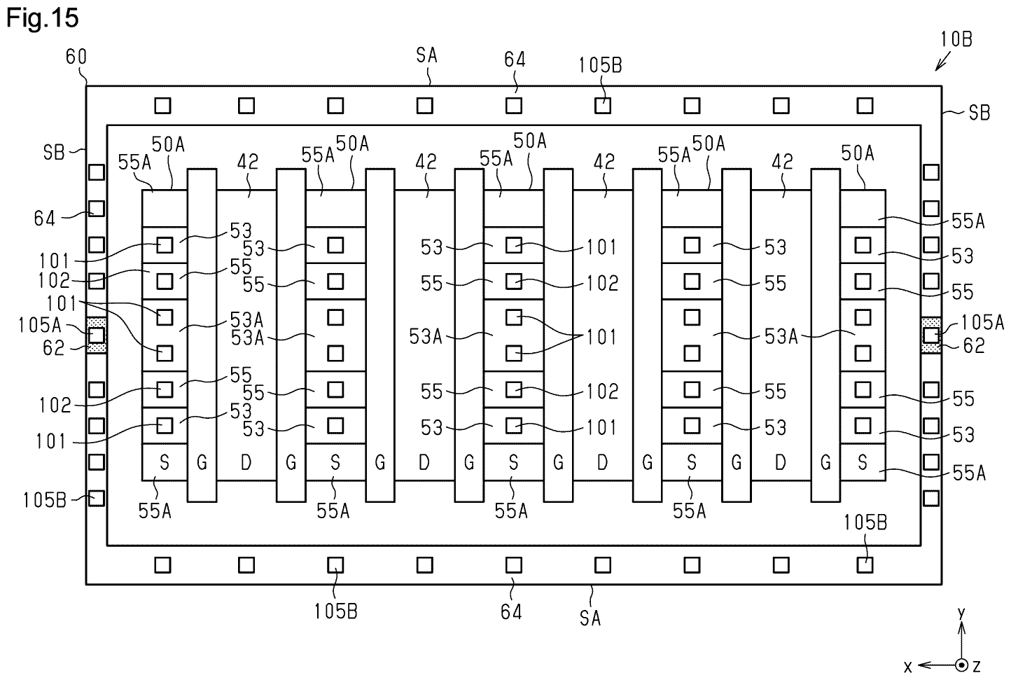

As shown in FIG. 15, multiple ring-side highly-doped regions 62 and multiple ring-side exposed regions 64 are formed in the ring-shaped region 60. The arrangement of the ring-side highly-doped regions 62 and the ring-side exposed regions 64 differs from that of the fifth and sixth modified examples.

In the seventh modified example, the ring-side highly-doped regions 62 are formed at only the center of each side SB in the y-direction. Thus, the total area of the ring-side exposed regions 64 is greater than the total area of the ring-side highly-doped regions 62. The difference between the total area of the ring-side exposed regions 64 and the total area of the ring-side highly-doped regions 62 is greater than that of the sixth modified example.

In the example shown, a ring-side first contact 105A is bonded to each ring-side highly-doped region 62. A ring-side second contact 105B forms a Schottky junction with each ring-side exposed region 64. In the seventh modified example, the number of ring-side second contacts 105B is greater than the number of ring-side first contacts 105A. In the seventh modified example, the number of ring-side second contacts 105B is greater than the number of ring-side second contacts 105B in the sixth modified example. With the structure of the seventh modified example, the positive ESD withstand voltage is further increased as compared to the sixth modified example.

As shown in FIGS. 13 to 15, in the fifth to seventh modified examples, the ring-side highly-doped regions 62 are symmetrically arranged with respect to the x-direction and the y-direction. In the fifth modified example, the ring-side highly-doped regions 62 are point-symmetrically arranged about the center of the element formation region. The ring-side exposed regions 64 are symmetrically arranged with respect to the x-direction and the y-direction. In the fifth modified example, the ring-side exposed regions 64 are point-symmetrically arranged about the center of the element formation region.

### Eighth Modified Example

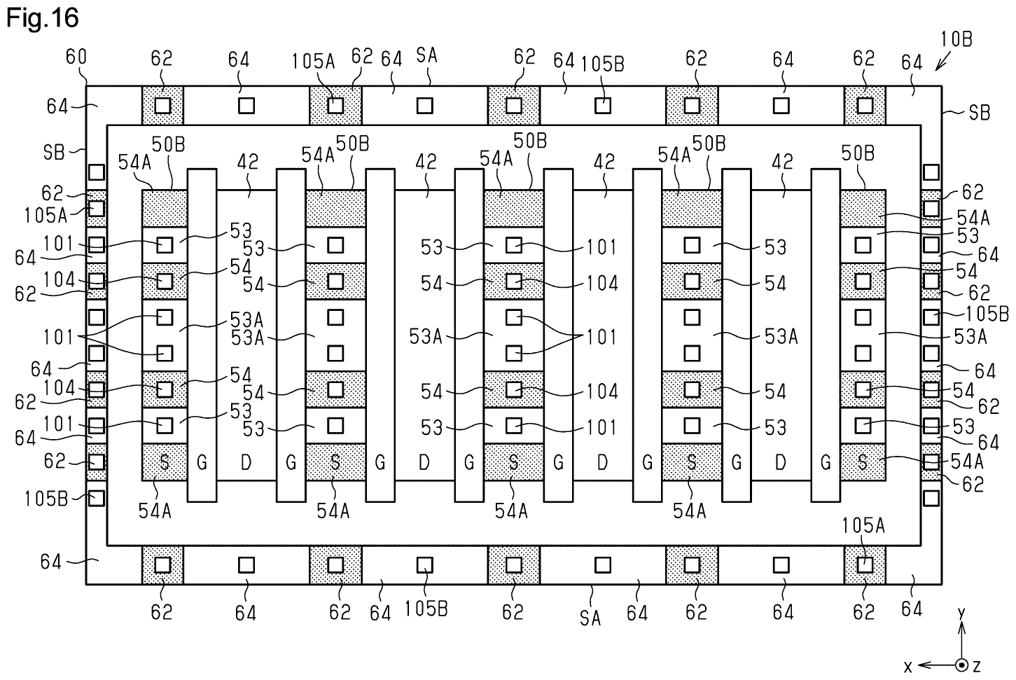

The arrangement of the highly-doped regions 54 and the exposed regions 55 and the arrangement of the ring-side highly-doped regions 62 and the ring-side exposed regions 64 may be changed in any manner. In an example, the arrangement may be changed as in an eighth modified example shown in FIG. 16.

As shown in FIG. 16, the first well region 50A is not formed in the element formation region. That is, five second well regions 50B are formed in the element formation region. The arrangement of the source regions 53 and the highly-doped regions 54 in each second well region 50B is the same as the arrangement of the source regions 53 and the highly-doped regions 54 in the second well region 50B of the first modified example. The arrangement of the first contact 101 and the fourth contact 104 in the second well region 50B is the same as the arrangement of the first contact 101 and the fourth contact 104 in the second well region 50B of the first modified example.

Multiple ring-side highly-doped regions 62 and multiple ring-side exposed regions 64 are formed in the ring-shaped region 60. The arrangement of the ring-side highly-doped regions 62 and the ring-side exposed regions 64 in the eighth modified example is the same as the arrangement of the ring-side highly-doped regions 62 and the ring-side exposed regions 64 in the fifth modified example.

The arrangement of the ring-side first contact 105A and the ring-side second contact 105B is the same as the arrangement of the ring-side first contact 105A and the ring-side second contact 105B of the fifth modified example.

The structure of the eighth modified example includes the ring-side exposed regions 64 and the ring-side second contacts 105B forming a Schottky junction with the ring-side exposed regions 64. Thus, the base-emitter voltage of the parasitic PNP transistor is increased in the second MOSFET 10B. This increases the current flowing to the second MOSFET 10B caused by ESD. Thus, the positive ESD withstand voltage of the second MOSFET 10B is increased.

The number of ring-side second contacts 105B is greater than the number of ring-side first contacts 105A bonded to the ring-side highly-doped regions 62. This increases the positive ESD withstand voltage of the second MOSFET 10B.

In the fifth to eighth modified examples, the ring-side first contacts 105A may be bonded to only some of the ring-side highly-doped regions 62. More specifically, the ring-side highly-doped regions 62 include ring-side highly-doped regions 62 that are bonded to the ring-side first contacts 105A and ring-side highly-doped regions 62 that are not bonded to the ring-side first contacts 105A.

In the fifth to eighth modified examples, the ring-side second contacts 105B may form a Schottky junction with only some of the ring-side exposed regions 64. More specifically, the ring-side exposed regions 64 may include ring-side exposed regions 64 that form a Schottky junction with the ring-side second contacts 105B and ring-side exposed regions 64 that do not form a Schottky junction with the ring-side second contacts 105B.

In the fifth to eighth modified examples, the structure located inward from the ring-shaped region 60 may be changed to that of any one of the first to fourth modified examples.

In the fifth to seventh modified examples, the structure located inward from the ring-shaped region 60 may be changed to each well region 50B of the eighth modified example.

In the first to third and eighth modified examples, the highly-doped regions 54 (end highly-doped regions 54A) may be asymmetrically arranged with respect to the x-direction or the y-direction.

In the first to seventh modified examples, the exposed regions 55 (end exposed regions 55A) may be asymmetrically arranged with respect to the x-direction or the y-direction.

### Modified Examples of Arrangement of Drain Region and Well Region

In the first to eighth modified examples, the arrangement of the drain region 42 (body region 40) may be changed in any manner. In an example, the drain regions 42 may be formed at opposite ends of the element formation region in the x-direction.

### Second Embodiment

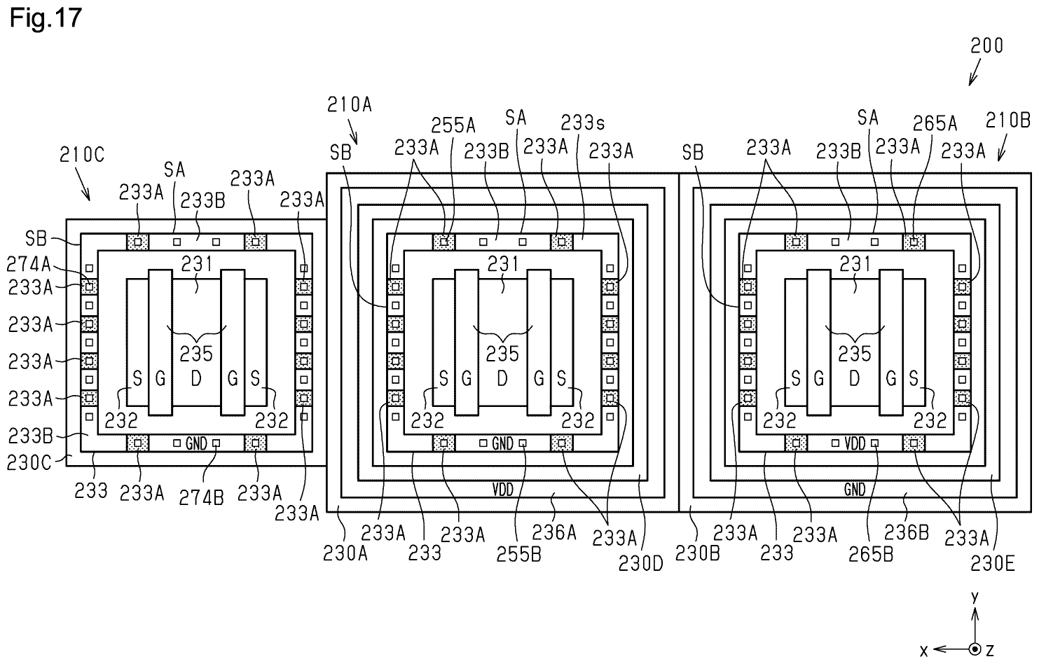

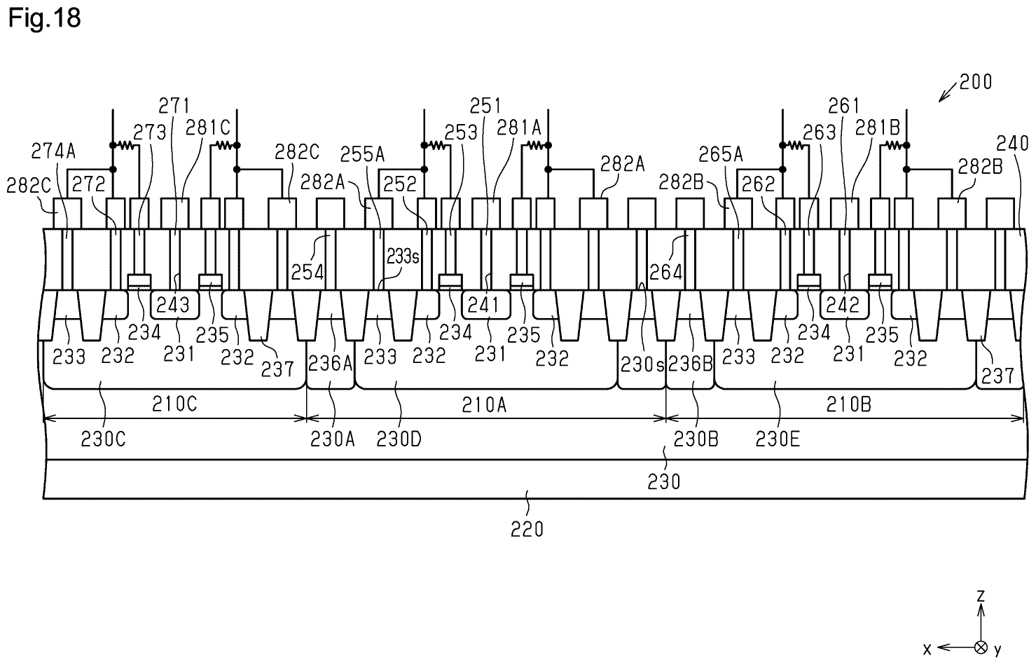

A second embodiment of a protection circuit 200 will now be described with reference to FIGS. 17 and 18. The protection circuit 200 of the second embodiment differs from the structure of MOSFETs from the protection circuit 10 of the first embodiment. FIG. 17 shows an example of an arrangement of first to third MOSFETs 210A to 210C of the protection circuit 200. FIG. 18 shows an example of a cross-sectional structure of the first to third MOSFETs 210A to 210C.

As shown in FIG. 17, the protection circuit 200 includes the first MOSFET 210A, the second MOSFET 210B, and the third MOSFET 210C. The first MOSFET 210A and the third MOSFET 210C are each an n-type MOSFET. The second MOSFET 210B is a p-type MOSFET. In the protection circuit 200, the connection structure of the MOSFETs 210A to 210C is the same as the connection structure (refer to FIG. 1) of the MOSFETs 10A to 10C of the first embodiment.

As shown in FIG. 17, the first MOSFET 210A, the second MOSFET 210B, and the third MOSFET 210C are arranged in the x-direction. The first MOSFET 210A is located between the second MOSFET 210B and the third MOSFET 210C in the x-direction.

As shown in FIG. 18, the protection circuit 200 includes a semiconductor substrate 220 of a second conductivity type (in the second embodiment, p-type) and a semiconductor layer 230 of the second conductivity type (in the second embodiment, p-type) formed on the semiconductor substrate 220. The dopant concentration of the semiconductor substrate 220 is, for example, the same as that of the first embodiment. In the second embodiment, the z-direction refers to the thickness-wise direction of the semiconductor layer 230. The phrase “plan view” includes the meaning of “view in the z-direction.” Thus, “plan view” includes the meaning of “view in the thickness-wise direction of the semiconductor layer.”

First to fifth epitaxial layers 230A to 230E are formed in a surface portion of the semiconductor layer 230. The first epitaxial layer 230A is a semiconductor layer of a first conductivity type (in the second embodiment, n-type) corresponding to the first MOSFET 210A. The second epitaxial layer 230B is a semiconductor layer of a second conductivity type (in the second embodiment, p-type) corresponding to the second MOSFET 210B and is formed adjacent to the first epitaxial layer 230A in the x-direction. The third epitaxial layer 230C is a semiconductor layer of the second conductivity type (in the second embodiment, p-type) corresponding to the third MOSFET 210C. The third epitaxial layer 230C and the second epitaxial layer 230B are located at opposite sides of the first epitaxial layer 230A in the x-direction. The fourth epitaxial layer 230D is a semiconductor layer of the second conductivity type (in the second embodiment, p-type) formed on the first epitaxial layer 230A in plan view. The fourth epitaxial layer 230D is separated from the second epitaxial layer 230B and the third epitaxial layer 230C in the x-direction. The fifth epitaxial layer 230E is a semiconductor layer of the first conductivity type (in the second embodiment, n-type) formed on the second epitaxial layer 230B. The fifth epitaxial layer 230E and the first epitaxial layer 230A are separated from each other in the x-direction.

Each of the epitaxial layers 230A to 230E has a higher dopant concentration than a portion of the semiconductor layer 230 located closer to the semiconductor substrate 220 than to each of the epitaxial layers 230A to 230E. The portion of the semiconductor layer 230 located closer to the semiconductor substrate 220 than to each of the epitaxial layers 230A to 230E has a dopant concentration that is, for example, the same as that of the semiconductor layer 30 (refer to FIG. 3) in the first embodiment. The dopant concentration of the epitaxial layers 230A to 230E is, for example, the same as that of the body region 40 (refer to FIG. 3) in the first embodiment.

The semiconductor layer 230 includes a surface 230s (surface of the third to fifth epitaxial layers 230C to 230E) in which drain regions 231, source regions 232, and a ring-shaped region 233 having the form of a ring surrounding the drain regions 231 and the source regions 232. In the first MOSFET 210A and the third MOSFET 210C, the drain regions 231 and the source regions 232 have the first conductivity type (in the second embodiment, n⁺-type), and the ring-shaped region 233 has the second conductivity type (in the second embodiment, p⁺-type). In the second MOSFET 210B, the drain regions 231 and the source regions 232 have the second conductivity type (in the second embodiment, p⁺-type), and the ring-shaped region 233 has the first conductivity type (in the second embodiment, n⁺-type). The drain regions 231, the source regions 232, and the ring-shaped region 233 each have a dopant concentration that is, for example, the same as that of the first embodiment.

A gate insulation film 234 is formed on the surface 230s of the semiconductor layer 230. A gate electrode 235 is formed on the gate insulation film 234. The gate insulation film 234 is formed from a material including, for example, silicon oxide (SiO₂). The gate insulation film 234 is formed to expose the drain regions 231 and the source regions 232. More specifically, the gate insulation film 234 is formed on the semiconductor layer 230 between the drain region 231 and the source region 232 in the x-direction. Thus, the gate electrodes 235 formed on the gate insulation films 234 are separated from each other in the x-direction. In plan view, the gate electrode 235 is arranged between the drain region 231 and the source region 232 in the x-direction.

As shown in FIG. 18, the first MOSFET 210A is formed on a surface of the fourth epitaxial layer 230D. In the second embodiment, the first MOSFET 210A includes one drain region 231, two source regions 232, two gate electrode 235, and a ring-shaped region 233 surrounding the drain regions 231 and the source regions 232.

The drain region 231 and the source regions 232 are arranged separately from each other in the x-direction. The drain region 231 is located between the source regions 232 in the x-direction. Thus, each source region 232 is located adjacent to the ring-shaped region 233 in the x-direction. In plan view, the gate electrode 235 is arranged between the drain region 231 and the source region 232. The drain region 231, the source regions 232, and the gate electrodes 235 each have the form of a strip elongated in the y-direction in plan view. In other words, the drain region 231, the source regions 232, and the gate electrodes 235 extend in the y-direction. Each of the source regions 232 is separated from the drain region 231 in the x-direction. The drain region 231 has a larger width-wise dimension (dimension in x-direction) than each source region 232. In the second embodiment, the y-direction corresponds to a “first direction.” The x-direction corresponds to a “second direction.”

A first peripheral region 236A is formed around the first MOSFET 210A to surround the ring-shaped region 233. The first peripheral region 236A is a semiconductor region that separates the first MOSFET 210A from the third MOSFET 210C. The first peripheral region 236A has the first conductivity type (in the second embodiment, n⁺-type). The first peripheral region 236A is formed on a surface of the first epitaxial layer 230A. The first peripheral region 236A is formed to surround the fourth epitaxial layer 230D. The first peripheral region 236A is, for example, electrically connected to the drain region 231.

The second MOSFET 210B is formed on a surface of the fifth epitaxial layer 230E. In the second embodiment, the second MOSFET 210B includes one drain region 231, two source regions 232, two gate electrodes 235, and a ring-shaped region 233 in the same manner as the first MOSFET 210A. The arrangement of these regions and the gate electrode 235 is the same as that of the first MOSFET 210A.

A second peripheral region 236B is formed around the second MOSFET 210B to surround the ring-shaped region 233. The second peripheral region 236B is a semiconductor region that separates the second MOSFET 210B from the first MOSFET 210A. The second peripheral region 236B has the second conductivity type (in the second embodiment, p⁺-type). The second peripheral region 236B is formed on a surface of the second epitaxial layer 230B. The second peripheral region 236B is formed to surround the fifth epitaxial layer 230E. The second peripheral region 236B includes a portion adjacent to the first peripheral region 236A. The second peripheral region 236B is, for example, electrically connected to the source regions 232.

The third MOSFET 210C is formed on a surface of the third epitaxial layer 230C. In the second embodiment, the third MOSFET 210C includes one drain region 231, two source regions 232, two gate electrodes 235, and a ring-shaped region 233 in the same manner as the first MOSFET 210A. The arrangement of these regions and the gate electrode 235 is the same as that of the first MOSFET 210A.

Multiple element separation strips 237 are formed in the surface 230s of the semiconductor layer 230. The element separation strips 237 are formed between the source region 232 and the ring-shaped region 233 in each of the MOSFETs 210A to 210C, between the first MOSFET 210A and the third MOSFET 210C, between the first MOSFET 210C and the second MOSFET 210B, and between each of the peripheral regions 236A and 236B and the ring-shaped region 233.

An insulation layer 240 is formed on the surface 230s of the semiconductor layer 230 to cover the gate electrode 235 and the element separation strip 237. The insulation layer 240 is formed from a material including, for example, SiO₂. The insulation layer 240 includes first openings 241, second openings 242, and third openings 243.

The first openings 241 are formed so that the drain region 231, the source regions 232, the gate electrodes 235, the ring-shaped region 233, and the first peripheral region 236A of the first MOSFET 210A are separately exposed from the insulation layer 240.

The second openings 242 are formed so that the drain region 231, the source regions 232, the gate electrodes 235, the ring-shaped region 233, and the second peripheral region 236B of the second MOSFET 210B are separately exposed from the insulation layer 240.

The third openings 243 are formed so that the drain region 231, the source regions 232, the gate electrodes 235, and the ring-shaped region 233 of the third MOSFET 210C are separately exposed from the insulation layer 240.

The protection circuit 200 includes first to fourth contacts 251 to 254 bonded to the first MOSFET 210A, first to fourth contacts 261 to 264 bonded to the second MOSFET 210B, and first to third contacts 271 to 273 bonded to the third MOSFET 210C.

The first to fourth contacts 251 to 254 are separately embedded in the first openings 241. The first contact 251 is bonded to the drain region 231 of the first MOSFET 210A. The second contacts 252 are bonded to the source regions 232 of the first MOSFET 210A. The third contacts 253 are bonded to the gate electrodes 235 of the first MOSFET 210A. The fourth contact 254 is bonded to the first peripheral region 236A.

The first to fourth contacts 261 to 264 are separately embedded in the second openings 242. The first contact 261 is bonded to the drain region 231 of the second MOSFET 210B. The second contacts 262 are bonded to the source regions 232 of the second MOSFET 210B. The third contacts 263 are bonded to the gate electrodes 235 of the second MOSFET 210B. The fourth contact 264 is bonded to the second peripheral region 236B.

The first to third contacts 271 to 273 are separately embedded in the third openings 243. The first contact 271 is bonded to the drain region 231 of the third MOSFET 210C. The second contacts 272 are bonded to the source regions 232 of the third MOSFET 210C. The third contacts 273 are bonded to the gate electrodes 235 of the third MOSFET 210C.

The first contacts 251, 261, and 271 are in ohmic contact with the drain region 231. The second contacts 252, 262, and 272 are in ohmic contact with the source regions 232. The third contacts 253, 263, and 273 are in ohmic contact with the gate electrodes 235. The fourth contact 254 is in ohmic contact with the first peripheral region 236A. The fourth contact 264 is in ohmic contact with the second peripheral region 236B.

The ring-shaped region 233 of the first to third MOSFETs 210A to 210C will now be described. For the sake of illustration, FIG. 17 show the contacts arranged in the ring-shaped region 233 and does not show the other contacts.

As shown in FIG. 17, in the second embodiment, the ring-shaped region 233 of each of the first to third MOSFETs 210A to 210C includes a surface 233s in which multiple highly-doped regions 233A are formed. The highly-doped regions 233A are separated from each other in a peripheral direction of the ring-shaped region 233. Thus, exposed regions 233B are formed in the surface 233s of the ring-shaped region 233 at positions differing from the highly-doped regions 233A in plan view. That is, the highly-doped regions 233A and the exposed regions 233B are alternately arranged in the ring-shaped region 233 in the peripheral direction.

The highly-doped region 233A has a higher dopant concentration than the ring-shaped region 233. In other words, the highly-doped region 233A has a higher dopant concentration than the exposed region 233B. In the second embodiment, the dopant concentration of the highly-doped region 233A is in a range of 1×10¹⁸ cm⁻³ to 1×10²⁰ cm⁻³. The dopant concentration of the exposed region 233B is in a range of 1×10¹⁵ cm⁻³ to 1×10¹⁷ cm⁻³. In an example, the highly-doped region 233A has the same dopant concentration as the source region 232. The exposed region 233B has the same dopant concentration as the ring-shaped region 233.

The ring-shaped region 233 is rectangular in plan view. The ring-shaped region 233 includes two sides SA separated in the y-direction and two sides SB separated in the x-direction. The two sides SA extend in the x-direction. In other words, the two sides SA extend in an arrangement direction of the drain region 231 and the source regions 232. The two sides SB extend in the y-direction. In other words, the two sides SB extend in a direction in which the drain region 231 and the source regions 232 extend.

In each side SA, multiple (in the second embodiment, two) highly-doped regions 233A are formed. The highly-doped regions 233A are opposed to the respective source regions 232 in the y-direction. In other words, the exposed regions 233B are opposed to the drain region 231 in the y-direction. The exposed regions 233B are also opposed to the gate electrodes 235 in the y-direction.

In each side SB, multiple (in the second embodiment, four) highly-doped regions 233A are formed. The highly-doped regions 233A are opposed to the respective source regions 232 in the x-direction. The highly-doped regions 233A are arranged in each side SB and separated from each other in the y-direction. Thus, multiple exposed regions 233B are formed in each side SB. The exposed regions 233B include exposed regions formed to be opposed to the source regions 232 in the x-direction. The exposed regions 233B further include exposed regions that are located on each side SB at a position differing from the source regions 232 in the y-direction. In the second embodiment, the exposed regions 233B are formed at four corners of the ring-shaped region 233.

As shown in FIG. 17, in each side SA, each exposed region 233B is greater in area than each highly-doped region 233A. In each of the MOSFETs 210A to 210C, the total area of the exposed regions 233B is greater than the total area of the highly-doped regions 233A.

A ring-side first contact 255A is bonded to each highly-doped region 233A of the first MOSFET 210A. The ring-side first contact 255A is in ohmic contact with the highly-doped region 233A. A ring-side second contact 255B forms a Schottky junction with each exposed region 233B of the first MOSFET 210A. The ring-side first contacts 255A and the ring-side second contacts 255B are embedded in the respective first openings 241. In the second embodiment, the number of ring-side second contacts 255B is greater than the number of ring-side first contacts 255A.

Some of the ring-side second contacts 255B are bonded to the exposed regions 233B that are located at a position differing from the source regions 232 in the y-direction. Some of the ring-side second contacts 255B are bonded to the exposed regions 233B that are opposed to the drain region 231 in the y-direction.

A ring-side first contact 265A is bonded to each highly-doped region 233A of the second MOSFET 210B. The ring-side first contact 265A is in ohmic contact with the highly-doped region 233A. A ring-side second contact 265B forms a Schottky junction with each exposed region 233B of the second MOSFET 210B. The arrangement of the ring-side contacts 265A and 265B is the same as the arrangement of the ring-side first contacts 255A and the ring-side second contacts 255B.

A ring-side first contact 274A is bonded to each highly-doped region 233A of the third MOSFET 210C. The ring-side first contact 274A is in ohmic contact with the highly-doped region 233A. A ring-side second contact 274B forms a Schottky junction with each exposed region 233B of the third MOSFET 210C. The arrangement of the ring-side contacts 274A and 274B is the same as the arrangement of the ring-side first contacts 255A and the ring-side second contacts 255B.

The number of highly-doped regions 233A may be changed in any manner. Also, the number of ring-side first contacts 255A and the number of ring-side second contacts 255B may be changed in any manner. In an example, the number of ring-side second contacts 255B may be equal to the number of ring-side first contacts 255A. In an example, the number of ring-side second contacts 255B may be less than the number of ring-side first contacts 255A. The number of ring-side first contacts 265A and 274A and the number of ring-side second contacts 265B and 274B may be changed in any manner, for example, in the same manner as the ring-side first contacts 255A and the ring-side second contacts 255B.

As shown in FIG. 18, the protection circuit 200 includes drain interconnects 281A to 281C and source interconnects 282A to 282C. The interconnects 281A to 281C and 282A to 282C are formed on the insulation layer 240. The interconnects 281A to 281C and 282A to 282C may be formed from a material including, for example, at least one of Cu, Al, and Ti. In the second embodiment, the source interconnects 282A to 282C each correspond to an “interconnect.”

The drain interconnect 281A is bonded to the first contact 251. The drain interconnect 281B is bonded to the first contact 261. The drain interconnect 281C is bonded to the first contact 271. Thus, the drain interconnect 281A is electrically connected to the drain region 231 of the first MOSFET 210A. The drain interconnect 281B is electrically connected to the drain region 231 of the second MOSFET 210B. The drain interconnect 281C is electrically connected to the drain region 231 of the third MOSFET 210C.

The source interconnect 282A electrically connects the ring-side first contact 255A, the ring-side second contact 255B, and the gate electrode 235 of the first MOSFET 210A to each other. More specifically, the source interconnect 282A is bonded to the second contact 252, the third contact 253, the ring-side first contact 255A, and the ring-side second contact 255B. Thus, the source interconnect 282A is electrically connected to the source region 232, the gate electrode 235, and the highly-doped region 233A and the exposed region 233B of the ring-shaped region 233 of the first MOSFET 210A.

The source interconnect 282B electrically connects the ring-side first contact 265A, the ring-side second contact 265B, and the gate electrode 235 of the second MOSFET 210B to each other. More specifically, the source interconnect 282B is bonded to the second contact 262, the third contact 263, the ring-side first contact 265A, and the ring-side second contact 255B. Thus, the source interconnect 282B is electrically connected to the source region 232, the gate electrode 235, and the highly-doped region 233A and the exposed region 233B of the ring-shaped region 233 of the second MOSFET 210B.

The source interconnect 282C electrically connects the ring-side first contact 274A, the ring-side second contact 274B, and the gate electrode 235 of the third MOSFET 210C to each other. More specifically, the source interconnect 282C is bonded to the second contact 272, the third contact 273, the ring-side first contact 274A, and the ring-side second contact 274B. Thus, the source interconnect 282C is electrically connected to the source region 232, the gate electrode 235, and the highly-doped region 233A and the exposed region 233B of the ring-shaped region 233 of the third MOSFET 210C.

In the protection circuit 200 having the configuration described above, a parasitic NPN transistor is formed between the drain and the source of each of the first MOSFET 210A and the third MOSFET 210C. The parasitic NPN transistor has collector electrically connected to the drain region 231, emitter electrically connected to the source region 232, and base electrically connected to the exposed region 233B or the highly-doped region 233A. When the base is connected to the exposed region 233B, each of the MOSFETs 210A and 210C has, between the base and the emitter of the parasitic NPN transistor, a resistance component of the exposed region 233B and a diode component due to a Schottky junction of the exposed region 233B and the ring-side second contacts 255B and 274B. Thus, the base-emitter voltage is likely to be increased. An increase in the base-emitter voltage facilitates the flow of a collector current.

In addition, a parasitic PNP transistor is formed between the drain and the source of the second MOSFET 210B. The parasitic PNP transistor has emitter electrically connected to the source region 232, collector electrically connected to the drain region 231, and base electrically connected to the exposed region 233B or the highly-doped region 233A. When the base is connected to the exposed region 233B, the second MOSFET 210B has, between the base and the emitter of the parasitic PNP transistor, a resistance component of the exposed region 233B and a diode component due to a Schottky junction with the exposed region 233B and the ring-side second contact 265B. Thus, the base-emitter voltage is likely to be increased. An increase in the base-emitter voltage facilitates the flow of a collector current.

### Advantages

The second embodiment obtains the following advantages.

(2-1) The protection circuit 200 including the first to third MOSFETs 210A, 210B, and 210C includes the semiconductor layer 230 of the second conductivity type, the drain region 231 of the first conductivity type formed on the surface 230s of the semiconductor layer 230 and extending in the y-direction, the source region 232 of the first conductivity type formed on the surface 230s of the semiconductor layer 230 and separated from the drain region 231 in the x-direction, the gate insulation film 234 formed on the semiconductor layer 230 between the drain region 231 and the source region 232, the gate electrode 235 formed on the gate insulation film 234, the ring-shaped region 233 being a ring-shaped semiconductor region of the second conductivity type to surround the drain region 231 and the source region 232, the highly-doped region 233A formed on the surface 233s of the ring-shaped region 233 and having a higher dopant concentration than the ring-shaped region 233, the exposed region 233B formed on the ring-shaped region 233 at a position differing from the highly-doped region 233A as viewed in the z-direction, the ring-side first contacts 255A, 265A, and 274A bonded to the highly-doped regions 233A, the ring-side second contacts 255B, 265B, and 274B forming a Schottky junction with the exposed regions 233B, and the source interconnects 282A to 282C electrically connecting the ring-side first contacts 255A, 265A, and 274A, the ring-side second contacts 255B, 265B, and 274B, and the gate electrode 235 to each other.

In this structure, a parasitic transistor is formed in each of the MOSFETs 210A to 210C, and the base of the parasitic transistor is electrically connected to the exposed region 233B. Thus, the collector current of the parasitic transistor is increased. This increases the current flowing to each of the MOSFETs 210A to 210C caused by ESD. Thus, the resistance of the protection circuit 200 to ESD is increased.

The protection circuit 200 is configured to allow adjustment of the number of ring-side first contacts 255A, 265A, and 274A bonded to the highly-doped regions 233A and the number of ring-side second contacts 255B, 265B, and 274B forming a Schottky junction with the exposed regions 233B. More specifically, in order to increase the positive ESD withstand voltage of the protection circuit 200, the number of ring-side second contacts 255B, 265B, and 274B forming a Schottky junction with the exposed regions 233B is increased. In order to increase the negative ESD withstand voltage of the protection circuit 200, the number of ring-side first contacts 255A, 265A, and 274A bonded to the highly-doped regions 233A is increased. Thus, the positive ESD withstand voltage and the negative ESD withstand voltage of the protection circuit 200 are adjustable in accordance with the number of ring-side contacts 255A, 265A, 274A, 255B, 265B, and 274B.

### Modified Examples of Second Embodiment

The second embodiment may be modified as follows. The modified examples described below may be combined with one another as long as there is no technical inconsistency.

In plan view, the arrangement direction of the first to third MOSFETs 210A to 210C may differ from the arrangement direction of the source regions 232 and the drain region 231. In an example, in plan view, the arrangement direction of the first to third MOSFETs 210A to 210C may be orthogonal to the arrangement direction of the source regions 232 and the drain region 231.

### Arrangement of Highly-Doped Region

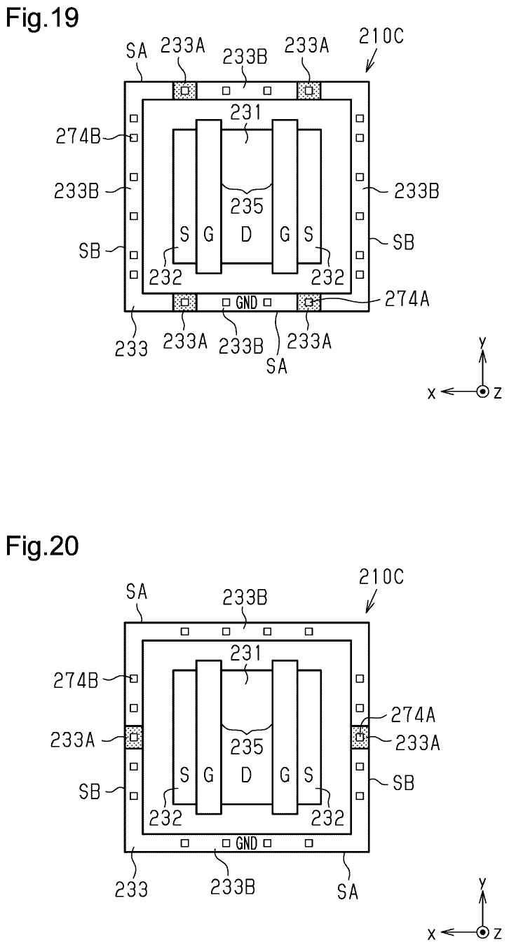

The arrangement of the highly-doped regions 233A in the ring-shaped region 233 may be changed in any manner. For example, the arrangement may be changed as in a first modified example shown in FIG. 19 or a second modified example shown in FIG. 20. FIGS. 19 and 20 do not show the first to third contacts 271 to 273.

### First Modified Example

As shown in FIG. 19, in the first modified example, the highly-doped region 233A is not formed in the sides SB of the ring-shaped region 233. Thus, each side SB of the ring-shaped region 233 is formed of only the exposed regions 233B. The arrangement of the highly-doped regions 233A in the sides SA of the ring-shaped region 233 is the same as that of the second embodiment.

As shown in FIG. 19, the number of exposed regions 233B in the first modified example is less than that of the second embodiment. Therefore, in each of the MOSFETs 210A to 210C, the difference between the total area of the exposed regions 233B and the total area of the highly-doped regions 233A is greater than that of the second embodiment.

In each side SB of the ring-shaped region 233, multiple (in the first modified example, six) ring-side second contacts 274B form a Schottky junction with the exposed regions 233B. Thus, in the first modified example, the number of ring-side second contacts 274B is greater than the number of ring-side first contacts 274A.

### Second Modified Example

As shown in FIG. 20, in the second modified example, the highly-doped region 233A is not formed in the sides SA of the ring-shaped region 233. Thus, each side SA of the ring-shaped region 233 is formed of only the exposed regions 233B. In each side SB of the ring-shaped region 233, the highly-doped region 233A is formed in a center of the side SB in the y-direction.

As shown in FIG. 20, in the first modified example, the number of exposed regions 233B is less than that of the first modified example. Therefore, in each of the MOSFETs 210A to 210C, the difference between the total area of the exposed regions 233B and the total area of the highly-doped regions 233A is greater than that of the first modified example.

In each side SA of the ring-shaped region 233, multiple (in the second modified example, four) ring-side second contacts 274B form a Schottky junction with the exposed regions 233B. In each side SB of the ring-shaped region 233, multiple (in the second modified example, four) ring-side second contacts 274B form a Schottky junction with the exposed regions 233B. Thus, in the second modified example, the number of ring-side second contacts 274B is greater than the number of ring-side first contacts 274A. The first modified example shown in FIG. 19 may be combined with the second modified example shown in FIG. 20.

### Modified Examples of Embodiments

The embodiments described above may be modified as follows. The embodiments described above and the modified examples described below can be combined as long as the combined modifications remain technically consistent with each other.

In the embodiments, the exposed regions 55 and 233B may not be formed in one or two of the first to third MOSFETs 10A to 10C (210A to 210C).

In the embodiments, the highly-doped regions 54 and 233A may not be formed in one or two of the first to third MOSFETs 10A to 10C (210A to 210C).

In the embodiments, the conductivity types of the first to third MOSFETs 10A to 10C (210A to 210C) may be inverted. More specifically, the first MOSFET 10A (210A) and the third MOSFET 10C (210C) may each be a p-type MOSFET, and the second MOSFET 10B (210B) may be an n-type MOSFET.

In the embodiments, the configuration of the protection circuits 10 and 200 may be changed in any manner. In an example, the third MOSFETs 10C and 210C mat be omitted from the protection circuits 10 and 200.

In this specification, “at least one of A and B” should be understood to mean “only A, or only B, or both A and B.”

In the present disclosure, the term “on” includes the meaning of “above” in addition to the meaning of “on” unless otherwise clearly indicated in the context. Therefore, the phrase “first member formed on second member” is intended to mean that the first member may be formed on the second member in contact with the second member in one embodiment and that the first member may be located above the second member without contacting the second member in another embodiment. In other words, the term “on” does not exclude a structure in which another member is formed between the first member and the second member.

The z-direction as referred to in the present disclosure does not necessarily have to be the vertical direction and does not necessarily have to be fully aligned with the vertical direction. In the structures according to the present disclosure, “upward” and “downward” in the z-direction as referred to in the present description are not limited to “upward” and “downward” in the vertical direction. In an example, the x-direction may be aligned with the vertical direction. In another example, the y-direction may be aligned with the vertical direction.

### Clauses

The technical aspects that are understood from the embodiments and the modified examples will be described below. To facilitate understanding without intention to limit, the reference signs of the elements in the embodiments are given to the corresponding elements in the clause with parentheses. The reference signs are used as examples to facilitate understanding, and the components in each clause are not limited to those components given with the reference signs.

### [Clause 1]

A semiconductor device (10), comprising:
a MOSFET (10A to 10C);
a semiconductor layer (30) of a first conductivity type;
a body region (40) of a second conductivity type formed on a surface (30s) of the semiconductor layer (30);
a drain region (42) of the second conductivity type formed on a surface (40s) of the body region (40) and separated from the semiconductor layer located around the body region (40), the drain region (42) extending in a first direction (y-direction) orthogonal to a thickness-wise direction (z-direction) of the semiconductor layer (30);
a first well region (50A) of the first conductivity type formed on the surface (30s) of the semiconductor layer (30) and separated from the drain region (42) in a second direction (x-direction) orthogonal to the thickness-wise direction (z-direction) of the semiconductor layer (30) and the first direction (y-direction);
a gate insulation film (85) formed on the semiconductor layer (30) between the first well region (50A) and the body region (40);
a field oxide film (80) formed on a portion of the surface (40s) of the body region (40) between the gate insulation film (85) and the drain region (42);
a gate electrode (10BG) formed on the gate insulation film (85) and the field oxide film (80);
a source region (53) of the second conductivity type formed on a surface (50s) of the first well region (50A);
an exposed region (55) formed in the first well region (50A) at a position differing from the source region (53) as viewed in the thickness-wise direction (z-direction) of the semiconductor layer (30);
a first contact (101) bonded to the source region (53);
a second contact (102) forming a Schottky junction with the exposed region (55);
a third contact (103) bonded to the gate electrode (10BG); and
an interconnect (110) electrically connecting the first contact (101), the second contact (102), and the third contact (103) to each other.

### [Clause 2]

The semiconductor device according to clause 1, further including:
a second well region (50B), in which the exposed region (55) is not formed, including the source region (53) and a highly-doped region (54) of the first conductivity type, the highly-doped region (54) being formed in a position differing from the source region (53) as viewed in the thickness-wise direction (z-direction) of the semiconductor layer (30); and
a fourth contact (104) bonded to the highly-doped region (54), in which
the highly-doped region (54) has a higher dopant concentration than the exposed region (55), and
the interconnect (110) is electrically connected to the fourth contact (104).

### [Clause 3]

The semiconductor device according to clause 2, in which
the first well region (50A), the second well region (50B), and the body region (40) are arranged in the second direction (x-direction), and
the first well region (50A) and the second well region (50B) are arranged at opposite sides of the body region (40) in the second direction (x-direction).

### [Clause 4]

The semiconductor device according to clause 2, in which
the body region (40), the first well region (50A), and the second well region (50B) are formed in an element formation region,
the second well region (50B) includes second well regions (50B) arranged at opposite ends of the element formation region in the second direction (x-direction), and
the first well region (50A) is arranged between the second well regions (50B), which are arranged at the opposite ends of the element formation region in the second direction (x-direction), in the second direction (x-direction).

### [Clause 5]

The semiconductor device according to clause 2, in which
the first well region (50A) includes multiple first well regions (50A),
the first well regions (50A), the second well region (50B), and the body region (40) are arranged in the second direction (x-direction),
the body region (40), the first well regions (50A), and the second well region (50B) are formed in an element formation region,
the second well region (50B) is arranged in a center of the element formation region in the second direction (x-direction), and
the first well regions (50A) are separately arranged at opposite sides of the second well region (50B) in the second direction (x-direction).

### [Clause 6]

The semiconductor device according to clause 2, in which
the first well region (50A) and the second well region (50B) are arranged at opposite sides of the body region (40) in the second direction (x-direction),
the first well region (50A) includes a highly-doped region (54) of the first conductivity type located in the first well region (50A) at a position differing from the source region (53) and the exposed region (55) as viewed in the thickness-wise direction (z-direction) of the semiconductor layer (30), the highly-doped region (54) having a higher dopant concentration than the first well region (50A), and
the highly-doped region (54) of the first well region (50A) and the highly-doped region (54) of the second well region (50B) are located at different positions in the first direction (y-direction).

### [Clause 7]

The semiconductor device according to clause 2, in which
the first well region (50A) includes a highly-doped region (54) of the first conductivity type located in the first well region (50A) at a position differing from the source region (53) and the exposed region (55) as viewed in the thickness-wise direction (z-direction) of the semiconductor layer (30), the highly-doped region (54) having a higher dopant concentration than the first well region (50A),
the highly-doped region (54) of the first well region (50A) is formed in only a center of the first well region (50A) in the first direction (y-direction), and
the highly-doped region (54) of the second well region (50B) is formed in only a center of the second well region (50B) in the first direction (y-direction).

### [Clause 8]

The semiconductor device according to any one of clauses 2 to 7, in which
the highly-doped region (54) has a dopant concentration of 1×10¹⁸ cm⁻³ or greater and 1×10²⁰ cm⁻³ or less, and
the exposed region (55) has a dopant concentration of 1×10¹⁵ cm⁻³ or greater and 1×10¹⁷ cm⁻³ or less.

### [Clause 9]

The semiconductor device according to any one of clauses 2 to 8, further including:
an intermediate region (51) that is a semiconductor region of the first conductivity type formed on the surface (50s) of the second well region (50B) and having a dopant concentration that is higher than a dopant concentration of the second well region (50B) and less than a dopant concentration of the highly-doped region (54), in which
the highly-doped region (54) is formed on a surface of the intermediate region (51), and
the intermediate region (51) is not formed and the exposed region (55) is formed in the first well region (50A) at a position differing from the source region (53) as viewed in the thickness-wise direction (z-direction) of the semiconductor layer (30).

### [Clause 10]

The semiconductor device according to any one of clauses 2 to 9, in which
the highly-doped region (54) includes multiple highly-doped regions (54), and
the highly-doped regions (54) are symmetrically arranged with respect to the first direction (y-direction) and the second direction (x-direction).

### [Clause 11]

The semiconductor device according to any one of clauses 2 to 10, further including:
a ring-shaped region (60) that is ring-shaped so as to surround the body region (40), the first well region (50A), and the second well region (50B);
a ring-side highly-doped region (62) formed on a surface (60s) of the ring-shaped region (60) and having a higher dopant concentration than the exposed region (55);
a ring-side exposed region (64) formed in the ring-shaped region (60) at a position differing from the ring-side highly-doped region (62) as viewed in the thickness-wise direction (z-direction) of the semiconductor layer (30), the ring-side exposed region (64) having a lower dopant concentration than the ring-side highly-doped region (62);
a ring-side first contact (105A) bonded to the ring-side highly-doped region (62); and
a ring-side second contact (105B) forming a Schottky junction with the ring-side exposed region (64).

### [Clause 12]

The semiconductor device according to clause 11, in which the ring-side exposed region (64) is equal in dopant concentration to the exposed region (55).

### [Clause 13]

A semiconductor device (200), including:
a MOSFET (210A to 210C);
a semiconductor layer (230) of a second conductivity type;
a drain region (231) of a first conductivity type formed on a surface (230s) of the semiconductor layer (230) and extending in a first direction (y-direction) orthogonal to a thickness-wise direction (z-direction) of the semiconductor layer (230);
a source region (232) of the first conductivity type formed on the surface (230s) of the semiconductor layer (230) and separated from the drain region (231) in a second direction (x-direction) orthogonal to the thickness-wise direction (z-direction) of the semiconductor layer (230) and the first direction (y-direction);
a gate insulation film (234) formed on the semiconductor layer (230) between the drain region (231) and the source region (232);
a gate electrode (235) formed on the gate insulation film (234);
a ring-shaped region (233) that is ring-shaped so as to surround the drain region (231) and the source region (232), the ring-shaped region (233) being a semiconductor region of the second conductivity type;
a highly-doped region (233A) formed on a surface of the ring-shaped region (233) and having a higher dopant concentration than the ring-shaped region;
an exposed region (233B) formed in the ring-shaped region (233) at a position differing from the highly-doped region (233A) as viewed in the thickness-wise direction (z-direction) of the semiconductor layer (230);
a ring-side first contact (255A, 265A, 274A) bonded to the highly-doped region (233A);
a ring-side second contact (255B, 265B, 274B) forming a Schottky junction with the exposed region (233B); and
an interconnect (282A, 282B, 282C) electrically connecting the ring-side first contact (255A, 265A, 274A), the ring-side second contact (255B, 265B, 274B), and the gate electrode (235) to each other.

### [Clause 14]

The semiconductor device according to clause 13, in which
the ring-shaped region (233) is rectangular as viewed in the thickness-wise direction (z-direction) of the semiconductor layer (230),
the ring-shaped region (233) has four sides including two sides (SA) separated in the first direction (y-direction) and two sides (SB) separated in the second direction (x-direction), and
the highly-doped region (233A) is formed in one of the four sides.

### [Clause 15]

The semiconductor device according to clause 14, in which the highly-doped region (233A) is formed in the two sides (SA) of the ring-shaped region (233) separated in the first direction (x-direction) and opposed to the source region (232) without being formed in the two sides (SB) of the ring-shaped region (233) separated in the second direction (x-direction).

### [Clause 16]

The semiconductor device according to clause 13, in which
the source region (232) includes multiple source regions (232),
the ring-shaped region (233) is rectangular as viewed in the thickness-wise direction (z-direction) of the semiconductor layer (230), and
as viewed in the thickness-wise direction (z-direction) of the semiconductor layer (230), the source regions (232) are arranged in the second direction (x-direction) in the ring-shaped region (233),
the source regions (232) are arranged at opposite ends in the second direction (x-direction) in the ring-shaped region (233),
the highly-doped region (233A) includes multiple highly-doped regions (233A) formed in two sides (SA) that are separated in the first direction (y-direction) and two sides (SB) that are separated in the second direction (x-direction),
the highly-doped regions (233A) formed in the two sides (SA) separated in the first direction (y-direction) are opposed to the source regions (232) in the first direction (y-direction), and
the highly-doped regions (233A) formed in the two sides (SB) separated in the second direction (x-direction) are opposed to the source regions (232) in the second direction (x-direction).

### [Clause 17]

The semiconductor device according to any one of clauses 13 to 16, in which
the highly-doped region (233A) has a dopant concentration of 1×10¹⁸ cm⁻³ or greater and 1×10²⁰ cm⁻³ or less, and
the exposed region (233B) has a dopant concentration of 1×10¹⁵ cm⁻³ or greater and 1×10¹⁷ cm⁻³ or less.

### [Clause 18]

The semiconductor device according to any one of clauses 1 to 10, in which
the exposed region (55) includes multiple exposed regions (55), and
the exposed regions (55) are symmetrically arranged with respect to the first direction (y-direction) and the second direction (x-direction).

### [Clause 19]

The semiconductor device according to any one of clauses 2 to 9, in which
the exposed region (55) includes multiple exposed regions (55),
the highly-doped region (54) includes multiple highly-doped regions (54), and
the exposed regions (55) and the highly-doped regions (54) are symmetrically arranged with respect to the first direction (y-direction) and the second direction (x-direction).

### [Clause 20]

The semiconductor device according to clause 11 or 12, in which
the ring-side highly-doped region (62) includes multiple ring-side highly-doped regions (62), and
the ring-side highly-doped regions (62) are symmetrically arranged with respect to the first direction (y-direction) and the second direction (x-direction).

### [Clause 21]

The semiconductor device according to any one of clauses 2 to 12, in which the second contact (102) is greater in number than the fourth contact (104).

### [Clause 22]

The semiconductor device according to any one of clauses 2 to 12, in which the fourth contact (104) is greater in number than the second contact (102).

### [Clause 23]

The semiconductor device according to any one of clauses 2 to 12, in which the second contact (102) is equal in number to the fourth contact (104).

### [Clause 24]

The semiconductor device according to clause 11 or 12, in which the ring-side second contact (105B) is greater in number than the ring-side first contact (105A).

### [Clause 25]

The semiconductor device according to clause 11 or 12, in which the ring-side first contact (105A) is greater in number than the ring-side second contact (105B).

### [Clause 26]

The semiconductor device according to clause 11 or 12, in which the ring-side first contact (105A) is equal in number to the ring-side second contact (105B).

### [Clause 27]

The semiconductor device according to any one of clauses 13 to 17, in which the ring-side second contact (255B, 265B, 274B) is greater in number than the ring-side first contact (255A, 265A, 274A).

### [Clause 28]

The semiconductor device according to any one of clauses 13 to 17, in which the ring-side first contact (255A, 265A, 274A) is greater in number than the ring-side second contact (255B, 265B, 274B).

### [Clause 29]

The semiconductor device according to any one of clauses 13 to 17, in which the ring-side first contact (255A, 265A, 274A) is equal in number to the ring-side second contact (255B, 265B, 274B).

### [Clause 30]

A semiconductor device (10) including:
a MOSFET (10A to 10C);
a semiconductor layer (30) of a first conductivity type;
a body region (40) of a second conductivity type formed on a surface (30s) of the semiconductor layer (30);
a drain region (42) of the second conductivity type formed on a surface (40s) of the body region (40) and separated from the semiconductor layer (30) located around the body region (40), the drain region (42) extending in a first direction (y-direction) orthogonal to a thickness-wise direction (z-direction) of the semiconductor layer (30);
a well region (50B) of the first conductivity type formed on the surface (30s) of the semiconductor layer (30) and separated from the drain region (42) in a second direction (x-direction) orthogonal to the thickness-wise direction (z-direction) of the semiconductor layer (30) and the first direction (y-direction);
a gate insulation film (85) formed on the semiconductor layer (30) between the well region (50B) and the body region (40);
a field oxide film (80) formed on a portion of the surface (40s) of the body region (40) between the gate insulation film (85) and the drain region (42);
a gate electrode (10BG) formed on the gate insulation film (85) and the field oxide film (80);
a source region (53) of the second conductivity type formed on a surface (50s) of the well region (50B);
a highly-doped region (54) of the first conductivity type formed in the well region (50B) at a position differing from the source region (53) as viewed in the thickness-wise direction (z-direction) of the semiconductor layer (30);
a ring-shaped region (60) that is ring-shaped so as to surround the body region (40) and the well region (50B);
a ring-side highly-doped region (62) formed on a surface (60s) of the ring-shaped region (60) and having a higher dopant concentration than the exposed region (55);
a ring-side exposed region (64) formed in the ring-shaped region (60) at a position differing from the ring-side highly-doped region (62) as viewed in the thickness-wise direction (z-direction) of the semiconductor layer (30), the ring-side exposed region (64) having a lower dopant concentration than the ring-side highly-doped region (62);
a ring-side first contact (105A) bonded to the ring-side highly-doped region (62);
a ring-side second contact (105B) forming a Schottky junction with the ring-side exposed region (64);
a source contact (101) bonded to the source region (53);
a gate contact (103) bonded to the gate electrode (10BG); and
an interconnect (110) electrically connecting the source contact (101), the gate contact (103), the ring-side first contact (105A), and the ring-side second contact (105B) to each other.

### [Clause 31]

The semiconductor device according to clause 30, in which the ring-side first contact (105A) is greater in number than the ring-side second contact (105B).

### [Clause 32]

The semiconductor device according to clause 30, in which the ring-side second contact (105B) is greater in number than the ring-side first contact (105A).

### [Clause 33]

The semiconductor device according to clause 30, in which the ring-side first contact (105A) is equal in number to the ring-side second contact (105B).

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims and the clauses.

1. A semiconductor device comprising:
a MOSFET;
a semiconductor layer of a first conductivity type;
a body region of a second conductivity type formed on a surface of the semiconductor layer;
a drain region of the second conductivity type formed on a surface of the body region and separated from the semiconductor layer located around the body region, the drain region extending in a first direction orthogonal to a thickness-wise direction of the semiconductor layer;
a first well region of the first conductivity type formed on the surface of the semiconductor layer and separated from the drain region in a second direction orthogonal to the thickness-wise direction of the semiconductor layer and the first direction;
a gate insulation film formed on the semiconductor layer between the first well region and the body region;
a field oxide film formed on a portion of the surface of the body region between the gate insulation film and the drain region;
a gate electrode formed on the gate insulation film and the field oxide film;
a source region of the second conductivity type formed on a surface of the first well region;
an exposed region formed in the first well region at a position differing from the source region as viewed in the thickness-wise direction of the semiconductor layer;
a first contact bonded to the source region;
a second contact forming a Schottky junction with the exposed region;
a third contact bonded to the gate electrode; and
an interconnect electrically connecting the first contact, the second contact, and the third contact to each other.

2. The semiconductor device according to claim 1, further comprising:
a second well region, in which the exposed region is not formed, including the source region and a highly-doped region of the first conductivity type, the highly-doped region being formed in a position differing from the source region as viewed in the thickness-wise direction of the semiconductor layer; and
a fourth contact bonded to the highly-doped region, wherein
the highly-doped region has a higher dopant concentration than the exposed region, and
the interconnect is electrically connected to the fourth contact.

3. The semiconductor device according to claim 2, wherein
the first well region, the second well region, and the body region are arranged in the second direction, and
the first well region and the second well region are arranged at opposite sides of the body region in the second direction.

4. The semiconductor device according to claim 2, wherein
the body region, the first well region, and the second well region are formed in an element formation region,
the second well region includes second well regions arranged at opposite ends of the element formation region in the second direction, and
the first well region is arranged between the second well regions, which are arranged at the opposite ends of the element formation region in the second direction, in the second direction.

5. The semiconductor device according to claim 2, wherein
the first well region includes multiple first well regions,
the first well regions, the second well region, and the body region are arranged in the second direction,
the body region, the first well regions, and the second well region are formed in an element formation region,
the second well region is arranged in a center of the element formation region in the second direction, and
the first well regions are separately arranged at opposite sides of the second well region in the second direction.

6. The semiconductor device according to claim 2, wherein
the first well region and the second well region are arranged at opposite sides of the body region in the second direction,
the first well region includes a highly-doped region of the first conductivity type located in the first well region at a position differing from the source region and the exposed region as viewed in the thickness-wise direction of the semiconductor layer, the highly-doped region having a higher dopant concentration than the first well region, and
the highly-doped region of the first well region and the highly-doped region of the second well region are located at different positions in the first direction.

7. The semiconductor device according to claim 2, wherein
the first well region includes a highly-doped region of the first conductivity type located in the first well region at a position differing from the source region and the exposed region as viewed in the thickness-wise direction of the semiconductor layer, the highly-doped region having a higher dopant concentration than the first well region,
the highly-doped region of the first well region is formed in only a center of the first well region in the first direction, and
the highly-doped region of the second well region is formed in only a center of the second well region in the first direction.

8. The semiconductor device according to claim 2, wherein
the highly-doped region has a dopant concentration of 1×10¹⁸ cm⁻³ or greater and 1×10²⁰ cm⁻³ or less, and
the exposed region has a dopant concentration of 1×10¹⁵ cm⁻³ or greater and 1×10¹⁷ cm⁻³ or less.

9. The semiconductor device according to claim 2, further comprising:
an intermediate region that is a semiconductor region of the first conductivity type formed on the surface of the second well region and having a dopant concentration that is higher than a dopant concentration of the second well region and less than a dopant concentration of the highly-doped region, wherein
the highly-doped region is formed on a surface of the intermediate region, and
the intermediate region is not formed and the exposed region is formed in the first well region at a position differing from the source region as viewed in the thickness-wise direction of the semiconductor layer.

10. The semiconductor device according to claim 2, wherein
the highly-doped region includes multiple highly-doped regions, and
the highly-doped regions are symmetrically arranged with respect to the first direction and the second direction.

11. The semiconductor device according to claim 2, further comprising:
a ring-shaped region that is ring-shaped so as to surround the body region, the first well region, and the second well region;
a ring-side highly-doped region formed on a surface of the ring-shaped region and having a higher dopant concentration than the exposed region;
a ring-side exposed region formed in the ring-shaped region at a position differing from the ring-side highly-doped region as viewed in the thickness-wise direction of the semiconductor layer, the ring-side exposed region having a lower dopant concentration than the ring-side highly-doped region;
a ring-side first contact bonded to the ring-side highly-doped region; and
a ring-side second contact forming a Schottky junction with the ring-side exposed region.

12. The semiconductor device according to claim 11, wherein the ring-side exposed region is equal in dopant concentration to the exposed region.

13. A semiconductor device, comprising:
a MOSFET;
a semiconductor layer of a second conductivity type;
a drain region of a first conductivity type formed on a surface of the semiconductor layer and extending in a first direction orthogonal to a thickness-wise direction of the semiconductor layer;
a source region of the first conductivity type formed on the surface of the semiconductor layer and separated from the drain region in a second direction orthogonal to the thickness-wise direction of the semiconductor layer and the first direction;
a gate insulation film formed on the semiconductor layer between the drain region and the source region;
a gate electrode formed on the gate insulation film;
a ring-shaped region that is ring-shaped so as to surround the drain region and the source region, the ring-shaped region being a semiconductor region of the second conductivity type;
a highly-doped region formed on a surface of the ring-shaped region and having a higher dopant concentration than the ring-shaped region;
an exposed region formed in the ring-shaped region at a position differing from the highly-doped region as viewed in the thickness-wise direction of the semiconductor layer;
a ring-side first contact bonded to the highly-doped region;
a ring-side second contact forming a Schottky junction with the exposed region; and
an interconnect electrically connecting the ring-side first contact, the ring-side second contact, and the gate electrode to each other.

14. The semiconductor device according to claim 13, wherein
the ring-shaped region is rectangular as viewed in the thickness-wise direction of the semiconductor layer,
the ring-shaped region has four sides including two sides separated in the first direction and two sides separated in the second direction, and
the highly-doped region is formed in one of the four sides.

15. The semiconductor device according to claim 14, wherein the highly-doped region is formed in the two sides of the ring-shaped region separated in the first direction and opposed to the source region without being formed in the two sides of the ring-shaped region separated in the second direction.

16. The semiconductor device according to claim 13, wherein
the source region includes multiple source regions,
the ring-shaped region is rectangular as viewed in the thickness-wise direction of the semiconductor layer, and
as viewed in the thickness-wise direction of the semiconductor layer, the source regions are arranged in the second direction in the ring-shaped region,
the source regions are arranged at opposite ends in the second direction in the ring-shaped region,
the highly-doped region includes multiple highly-doped regions formed in two sides that are separated in the first direction and two sides that are separated in the second direction,
the highly-doped regions formed in the two sides separated in the first direction are opposed to the source regions in the first direction, and
the highly-doped regions formed in the two sides separated in the second direction are opposed to the source regions in the second direction.

17. The semiconductor device according to claim 13, wherein
the highly-doped region has a dopant concentration of 1×10¹⁸ cm⁻³ or greater and 1×10²⁰ cm⁻³ or less, and
the exposed region has a dopant concentration of 1×10¹⁵ cm⁻³ or greater and 1×10¹⁷ cm⁻³ or less.
